(19) United States
(12) Patent Application Publication
(10) Pub. No.: US 2014/0011323 A1
(43) Pub. Date: Jan. 9, 2014

(54) PROCESSES RELATING TO CLEANSPACE FABRICATORS

(71) Applicant: Frederick Flitsch, New Windsor, NY (US)

(72) Inventor: Frederick Flitsch, New Windsor, NY (US)

(21) Appl. No.: 13/838,642

(22) Filed: Mar. 15, 2013

Related U.S. Application Data
(60) Provisional application No. 61/668,853, filed on Jul. 6, 2012.
(60) Provisional application No. 61/668,853, filed on Jul. 6, 2012.

(51) Int. Cl. H01L 21/78; B65G 47/74

(52) U.S. Cl. CPC H01L 21/78; B65G 47/74
USPC 438/106; 414/806

(57) ABSTRACT

The present invention provides various methods for utilizing aspects of cleanspace fabricators. In some embodiments methods related to the development of tooling in applications or “apps” type models are discussed. In other embodiments methods related to product development based on crowd sourcing are discussed. In other embodiments licensing models for design blocks, process flows, assembly processing and assembly related intellectual processing are discussed.

### CROSS REFERENCE TO RELATED APPLICATIONS

This application is a non-provisional filing to the U.S. Provisional Patent Application bearing the Ser. No. 61/668853, filed Jul. 6, 2012 and entitled Business Processes Relating to Cleanspace Fabricators. The contents are relied upon and incorporated by reference.

### FIELD OF THE INVENTION

The present invention relates to methods and associated apparatus and methods which relate to processing tools used in conjunction with cleanspace fabricators. More specifically, the present invention relates to methods and apparatus to capitalize on the advantages of cleanspace fabricators for methods or development, design, research and manufacturing. In some embodiments, smaller embodiments than factories are described.

### BACKGROUND OF THE INVENTION

A known approach to advanced technology fabrication of materials such as semi-conductor substrates is to assemble a manufacturing facility as a “cleanroom.” In such cleanrooms, processing tools are arranged to provide aisle space for human operators or automation equipment. Exemplary cleanroom design is described in: “Cleanroom Design, Second Edition,” edited by W. Whyte, published by John Wiley & Sons, 1999, ISBN 0-471-94204-9, (herein after referred to as “the Whyte text” and the content of which is included for reference in its entirety).

Cleanroom design has evolved over time to include locating processing stations within clean hoods. Vertical unidirectional airflow can be directed through a raised floor, with separate cores for the tools and aisles. It is also known to have specialized mini-environments which surround only a processing tool for added space cleanliness. Another known approach includes the “ballroom” approach, wherein tools, operators and automation all reside in the same cleanroom.

Evolutionary improvements have enabled higher yields and the production of devices with smaller geometries. However, known cleanroom design has disadvantages and limitations.

For example, as the size of tools has increased and the dimensions of cleanrooms have increased, the volume of cleanspace that is controlled has concomitantly increased. As a result, the cost of building the cleanspace, and the cost of maintaining the cleanliness of such cleanspace, has increased considerably.

Tool installation in a cleanroom can be difficult. The initial “fit up” of a “fab” with tools, when the floor space is relatively empty, can be relatively straightforward. However, as tools are put in place and a fabricator begins to process substrates, it can become increasingly difficult and disruptive of job flow, to either place new tools or remove old ones Likewise it has been difficult to remove a sub-assembly or component that makes up a fabricator tool in order to perform maintenance or replace such a subassembly or component of the fabricator tool. It would be desirable therefore to reduce installation difficulties attendant to dense tool placement while still maintaining such density, since denser tool placement otherwise affords substantial economic advantages relating to cleanroom construction and maintenance.

There are many types of manufacturing flows and varied types of substrates that may be operated effectively in the mentioned novel cleanspace environments. It would be desirable to define standard methodology of design and use of standard componentry strategies that would be useful for manufacturing flows of various different types; especially where such flows are currently operated in non-cleanroom environments.

### SUMMARY OF THE INVENTION

Accordingly, the present invention provides novel methods of utilizing the design for processing fabs which rearrange the clean room into a cleanspace and thereby allow processing tools to reside in both vertical and horizontal dimensions relative to each other and in some embodiments with their tool bodies outside of, or on the periphery of, a clean space of the fabricator. In such a design, the tool bodies can be removed and replaced with much greater ease than is the standard case. The design also anticipates the automated transfer of substrates inside a clean space from a tool port of one tool to another. The substrates can reside inside specialized carriers designed to carry ones substrate at a time. Further design enhancements can entail the use of automated equipment to carry and support the tool body movement into and out of the fab environment. In this invention, numerous methods of using some or all of these innovations in designing, operating or otherwise interacting with such fabricator environments are described. The present invention can therefore include methods and apparatus for situating processing tools in a vertical dimension and control software modules for making such tools functional both within the cleanspace entity itself and also in networks of such fabricators.

In some embodiments of the invention, methods are provided which utilize at least one fabricator where the cleanspace is vertically deployed. Within said fabricator there will be at least one and typically more tool chassis and toolPods. A toolPod will typically be attached to a tool chassis directly or indirectly thorough one or more other piece or pieces of equipment which attach to the toolPod. At least the one fabricator will perform a process in one of the toolPods and typically will perform a process flow which will be performed in at least one toolPod. The toolPod may have an attached or integral Toolport that is useful for the transport of substrates from one tool or toolPod to another tool or toolPod. In these embodiments, a unique aspect of the embodiments is that the first toolPod may be removed from the fabricator or factory for a maintenance activity or repair and then replaced with another toolPod. The use of the tool chassis together with a toolPod may result in a replacement that takes less than a day to perform. In some cases the replacement may take less than an hour. There may be numerous reasons for the replacement. It may be to repair the first toolPod or it may be replace the toolPod with another toolPod where the tool within is of a different or newer design type. These methods may be additionally useful to product a product when the substrate produced by the process flow may next be processed with additional steps including those which dice or cut or segment the substrate into subsections which may be called chips. The chips may then be assembled into packages to form a product. The assembly and packaging steps may also comprise a process flow and may include sophisticated techniques including three dimensional assembly, through silicon vias, substrate stacking to mention a few; and these steps may be performed in a cleanspace fabricator or alternatively in a cleanroom type fabricator. The assembly and packaging operations may include steps for thinning substrates as well as steps to form conductive connections between conductive contacts or contacts and other conductive surfaces. Alternatively, the end product of the assembly and packaging operations which may be an assembled product may be used in method where a conductive connection is formed between a conductive contact of the package and another conductive surface of another component or entity.

In other embodiments of the invention, the toolPod may be useful for other methods relating to the development of tools. A toolPod in some embodiments may contain a subset of parts that are standard for a great many types of toolPods for example such parts may include control or computing systems, gas flow or liquid flow components, radio frequency signal generators, power supplies, clean air flow components, thermal regulation components and the like. A toolPod may therefore be formed in an incomplete form where a processing chamber is not present. It may be possible that only the processing chamber is not present or the processing chamber and some other components are not present. A method of developing a tool may involve taking the incomplete toolPod and designing a process chamber to go inside of it. Additional components to the process chamber may also be designed to go into the toolPod or in some embodiments changes to the standard components may be developed and implemented. The new designed toolPod comprising an incomplete toolPod and either or both of new chambers and new components may be produced. This newly designed tool in a toolPod may be tested for functionality. These tests may be performed on test stands that mate, support, connect or interact with the new toolPod. Alternatively, the tests may be performed by mating the toolPod with a Tool Chassis. The designer of the new tool may determine the functionality of the tool or alternatively a different entity may receive the new tool in a toolPod and perform the tests. A description of the function including a statement of qualification or something equivalent may be given. A different entity may offer the tool for sale, rent, leasing or as a portion of a larger entity that may be sold or leased.

In other embodiments of the invention, the fabricator described above and the methods described above may be repeated to occur in a multiple of fabricators. These combinations of fabricators may form a network of fabricators. The network of fabricators may have means of communication amongst and between the various fabricators. A method may involve a customer distributing a need for a part utilizing communication systems that interact with the individual fabricators. The communication of need for the part may be received in various fashions by the fabricator or affiliated users of the fabricators. The fabricator or user of the fabricator may assess the ability to provide a product meeting the need communicated and then utilize one or more of the networked fabricators to produce the product. In the process of designing such a part or more globally any part, the designing entity may elect to use intellectual property of others to form their product wherein said intellectual property has been duly offered for use either by free public domain type use or licensed use. The network or individual fabs may receive payments for the production of a product and may facilitate the payment of royalty payments to intellectual property holders as appropriate.

In some embodiments, the methods of producing products in the mentioned cleanspace fabricator types and the methods of developing tools may be utilized to define new entities for large scale manufacturing. By combining large numbers of small volume processing tools the fabricators may produce large amounts of product. In a unique manner, the tools may be further developed to simplify operations and thus lower cost.

The simplification may include rationalizing the components and the design of processing chambers to the minimum or at least a lowered complexity so that limited processes may be performed in the tools. As an example, a mass flow controller capable of operation over a wide range of selectable gas flow requirements may be replaced with a pressure regulator and an orifice capable of providing a controllable flow within a single narrow flow condition.

In some embodiments, the methods of producing products in the mentioned cleanspace fabricator may be useful to produce small amounts of a product. In some cases the small amounts may be the early amounts of the product that will be produced in its lifetime. A user may produce these volumes with the intent of scaling up the production in other fabrication entities which may be of a cleanspace or a cleanroom fabricator or other type. In some embodiments, using this process the user may produce a product in a number of process flows each intended to generate a product acceptable within that product's specifications but where the processing flow will allow the production to be performed in more than one large volume fabricator or in a selection of one amongst a number of large volume fabricators. In other aspects of this type of embodiment the method of producing product in different process flows may be useful for the purpose of producing different populations of product where the performance aspect of the different populations may be compared against each other. A designer may utilize such performance comparisons to produce one of the types of flows or alternatively more than one grade of product in multiple production environments.

In some embodiments, the methods of utilizing cleanspace fabricators that have been discussed involve the removal of a toolPod from a fabricator or factory. After such removal, in some embodiments the toolPod may be disposed of. In other embodiments, the toolPod may be recycled. In still other embodiments the toolPod may be sent to a maintenance facility. The maintenance facility may be located within the confines of the business entity which removed the toolPod or alternatively in a remote maintenance facility. If the maintenance will be prepared in a remote facility the toolPod may be shipped by various means including land transportation of automobiles, trucks, or trains or similar conveyances or by water transportation including ships for example or by air transportation means. In some embodiments, once the toolPod reaches a maintenance facility it may be transported to a location within a cleanspace or a cleanroom where maintenance activity may be performed. In the performance of the maintenance activity the toolPod may be disassembled at least in part to allow for access of maintenance personnel or equipment to components within the toolPod. Alternatively automated diagnostic equipment may perform tests and perform maintenance without a disassembly step in some cases. After the toolPod is maintained it may be reassembled as necessary and then tested. It may be tested on a test stand or placed upon a tool chassis. The tests may involve functional tests of the components or involve tests upon substrates which are monitors or substrates representative of product. The toolPod may thereafter be shipped to the same location it came from or another different location. At the same location, if shipped there it may be placed at a later time on the same Tool Chassis it was mated with previously or alternatively it may be placed on a different Tool Chassis.

In some embodiments of the invention, novel methods of research and development may be performed. Utilizing the methods related to cleanspace fabricators that have been mentioned or are mentioned in other sections of this specification, at least one of the toolPods utilized may be an experimental tool design. Alternatively, an established tool design may be used for an experimental process module. Alternatively, experimental assembly or packaging techniques may be performed on the resulting substrate of the cleanspace fabricator or in cleanspace fabricators themselves. The processing may involve the use of new processing flows at least in part in toolPods within cleanspace fabricators of various types. The processing may involve new designs produced in processing flows at least in part in toolPods within cleanspace fabricators of various types.

There may be combinations of toolPods and tool Chassis entities which reside in environments that resemble either cleanspace or cleanroom environments which represent novel methods based on the inventive art herein. For example, a vertically deployed cleanspace may exist in an environment where there is only one vertical level in the fabricator or where there are no toolPods located in a vertical orientation where at least a portion of a toolPod lies above another in a vertical direction. Alternatively, whether in only one vertical level or in multiple levels of a cleanspace fabricator type whether vertically deployed or not there may be novel embodiments of the inventive art herein that involve collections of toolPods that are functional to produce on a portion of a process flow or even a portion of a process but utilize the methods described for fabricators and are novel as well.

### BRIEF DESCRIPTION OF THE DRAWINGS

The accompanying drawings, that are incorporated in and constitute a part of this specification, illustrate several embodiments of the invention and, together with the description, serve to explain the principles of the invention:

FIG. 1—A depiction of the changes related to cleanspace fabricators and the size differences that are possible from the state of the art.

FIG. 2—An illustration of a small tool cleanspace fabricator in a sectional type representation.

FIG. 3—An illustration of an application or “Apps” model for tool pods.

FIG. 4—A flowchart representation of an application model applied to processing tools.

FIG. 5—A depiction of process flow for Crowd Sourcing where fabricators are networked with each other.

FIG. 6—A flowchart representation of a crowd sourcing model in cleanspace fabricators.

FIG. 7—Licensing for design, process and packaging details

FIG. 8—A flowchart representation of licensing models

FIG. 9—Depiction of methods of communication

FIG. 10—A Flowchart representation of a process for producing large volumes of production using smaller wafer sized tools.

FIG. 11—A Flow chart depicting qualifying a design in multiple process flows in a cleanspace fabricator network.

FIG. 12—A maintenance facility at an external location

FIG. 13—A flow chart for the processes of operating external maintenance facilities

FIG. 14—A Flow chart for qualifying tools after repair

FIG. 15—New Research and Development in multiple locations.

FIG. 16—A depiction of sub fabricator application of some cleanspace fabricator related innovations.

### DETAILED DESCRIPTION OF PREFERRED EMBODIMENTS

In patent art by the same inventive entity, the innovation of the cleanspace fabricator has been described. In place of a cleanroom, fabricators of this type may be constructed with a cleanspace that contains the wafers, typically in containers, and the automation to move the wafers and containers around between ports of tools. The cleanspace may typically be much smaller than the space a typical cleanroom may occupy and may also be envisioned as being turned on its side. In some embodiments, the processing tools may be shrunk which changes the processing environment further.

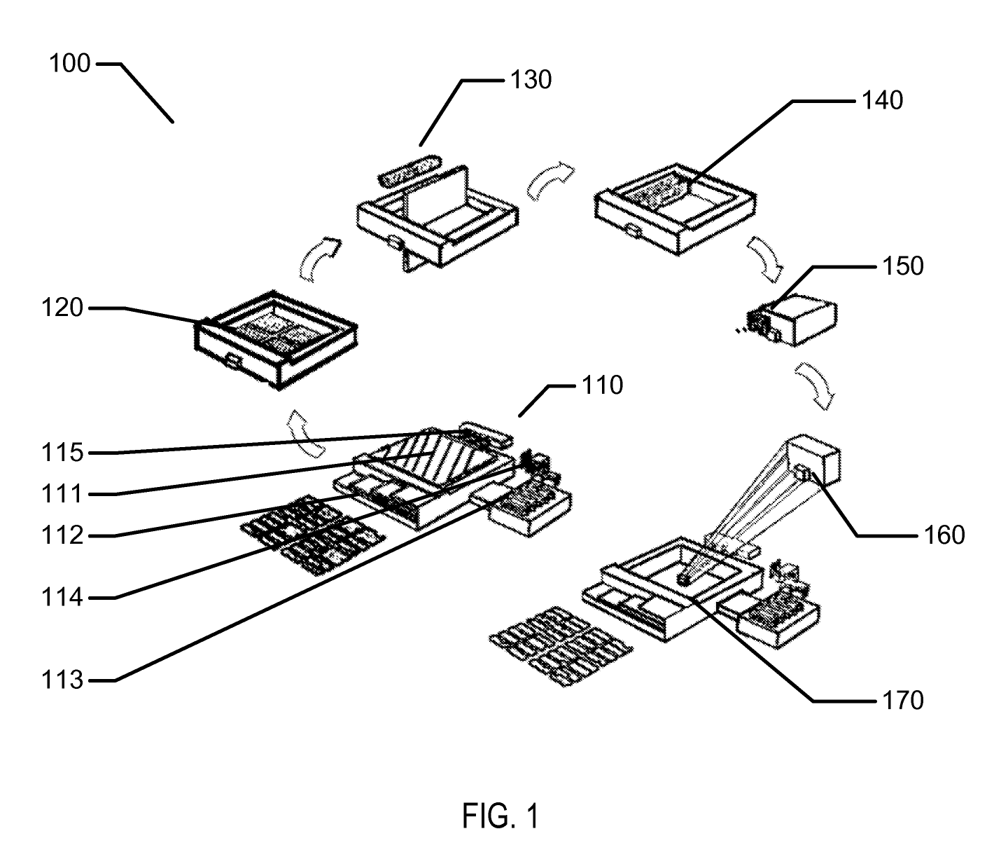

In FIG. 1, item 100, a depiction of the changes possible with a cleanspace fabricator is described. In Item 110, a typical cleanroom based fabrication site is depicted. Item 111, may represent the cleanroom, item 112 may represent office space for the various functions to support the production, item 113 may represent facilities to control and generate the necessary utilities including clean room air which may be temperature and humidity controlled, item 114 may represent facilities for gasses and chemicals. Item 115 may represent safety and fire control operations.

Continuing on FIG. 1, the advantages of a cleanspace fabricator allow for less capacity needs for the support facilities. Especially when the fabricator is focused in small volumes these facilities may be greatly reduced. The representation of item 120 shows the cleanroom space alone where the tools are now seen through the ceiling of the facility which would be where the cleanroom air filters would typically be located. The size of the cleanroom is still roughly 6 football fields in size. This depiction may represent the reduced site services aspect of cleanspace fabricators.

In a cleanspace fabricator, the cleanroom is replaced with the cleanspace. Proceeding to item 130 in FIG. 1, a representation of a change in the cleanroom is depicted. In some embodiments, a cleanspace may be envisioned by the process of rotating a fab's cleanroom on its side. After this, the dimension of the thus rotated cleanroom may then be shrunk by up to a factor of tenfold. The tools are represented as being removed from the cleanroom environment and “hovering” about the facility. This changed cleanspace dimension is one of the reasons for the reduced amount of site service requirements.

Proceeding further, item 140 demonstrates the placement in some embodiments of tooling in a vertical dimension. The tools that were hovering above the facility are now shown as being oriented next to the cleanspace environments in a vertically oriented or stacked orientation. These tool all about both the cleanspace and also a region external to the cleanspace and thus all exist on the periphery. Therefore, item 140 may represent the peripheral tool access aspect of the cleanspace fabricator. What may be apparent is that this type of orientation of the tooling also allows for the further shrinkage of the fabricator dimension required.

In some embodiments, a shrunken version of the fab due only to the orientation of tooling may result even when the same numbers of tools are utilized. However, due to a variety of aspects of the cleanspace fabricator, there may be operational modes that make business sense to organize a minimal number of tools into a cleanspace type facility. Such a reduced number of tools may result in the reduced fab footprint as depicted in item 150. However, still further embodiments of the operational and business models may derive if the tools themselves are reduced in size so that they process wafers that are roughly 2 inches in diameter or at least significantly smaller than standard dimensions. Another point made in the depiction of item 150 shows that the tools may be shrunken to create another version of the cleanspace fabricator.

Item 160 may show the further reduced footprint of a cleanspace fabricator whose purpose in some embodiments may be a focus on activities of small volume. In these type of embodiments, the small tools occupy less space than large tools further reducing the space of the cleanspace and thus the site support aspects of fabricators the extreme of which has been depicted in the figure starting with item 120. If such a prototype fabricator as item 160 is placed within the original footprint item 170 it may be clear the significant scale differences that are possible.

### Description of a Linear, Vertical Cleanspace Fabricator

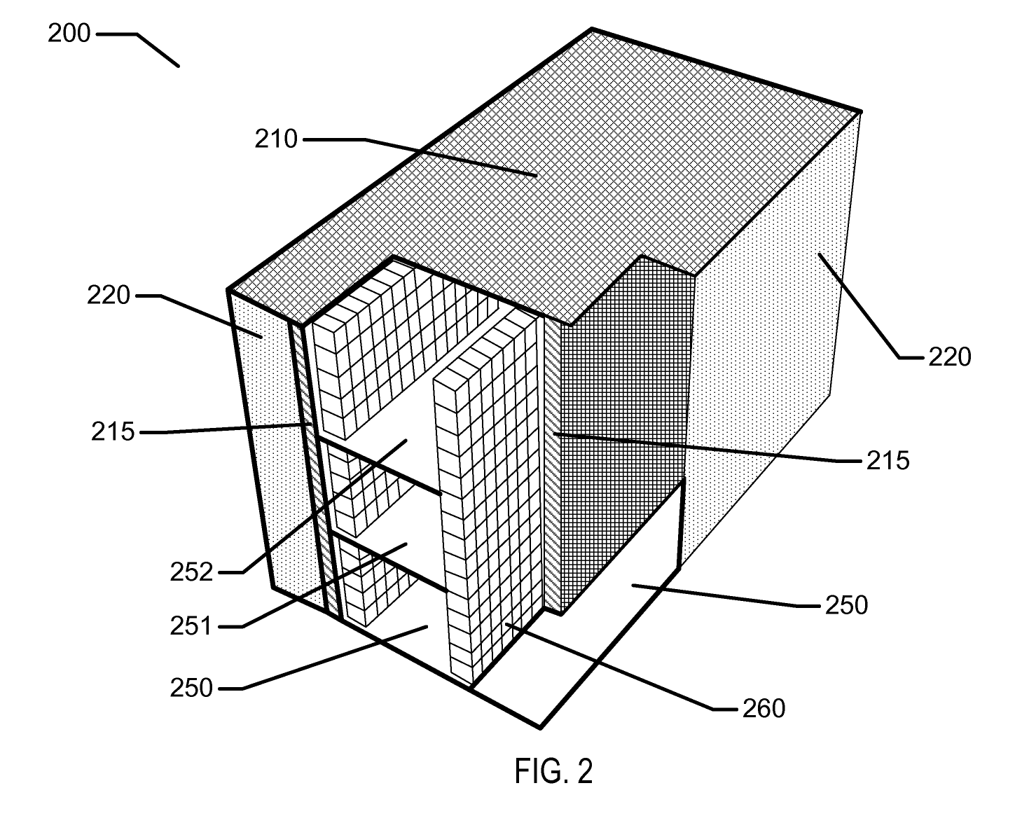

There are a number of types of cleanspace fabricators that may be possible with different orientations. For the purposes of illustration one exemplary type where the fab shape is planar with tools oriented in vertical orientations may be used. This type may result in the depictions shown in FIG. 1. An exemplary representation of what the internal structure of these types of fabs may look like is shown in a partial cross section representation in FIG. 2, item 200. Item 210 may represent the roof of such a fabricator where some of the roof has been removed to allow for a view into the internal structure. Additionally, items 220 may represent the external walls of the facility which are also removed in part to allow a view into external structure.

In the linear and vertical cleanspace fabricator of FIG. 2 there are a number of aspects that may be observed in the representation. The “rotated and shrunken” cleanspace regions may be observed as items 215. The occurrence of item 215 on the right side of the figure is depicted with a portion of its length cut off to show its rough size in cross section. The cleanspaces lie adjacent to the tool pod locations. Depicted as item 260, the small cubical features represent tooling locations within the fabricator. These locations are located vertically and are adjacent to the cleanspace regions (215). In some embodiments a portion of the tool, the tool port, may protrude into the cleanspace region to interact with the automation that may reside in this region.

Items 250 may represent the fabricator floor or ground level. On the right side, portions of the fabricator support structure may be removed so that the section may be demonstrated. In between the tools and the cleanspace regions, the location of the floor 250 may represent the region where access is made to place and replace tooling. In some embodiment, as in the one in FIG. 2, there may be two additional floors that are depicted as items 251 and 252. Other embodiments may have now flooring levels and access to the tools is made either by elevator means or by robotic automation that may be suspended from the ceiling of the fabricator or supported by the ground floor and allow for the automated removal, placement and replacement of tooling in the fabricator.

### Description of a Chassis and a Toolpod or a Removable Tool Component

In other patent descriptions of this inventive entity (patent application Ser. No. 11/502,689 which is incorporated in its entirety for reference) description has been made of the nature of the toolPod innovation and the toolPod's chassis innovation. These constructs, which in some embodiments may be ideal for smaller tool form factors, allow for the easy replacement and removal of the processing tools. Fundamentally, the toolPod may represent a portion or an entirety of a processing tool's body. In cases where it may represent a portion, there may be multiple regions of a tool that individually may be removable. In either event, during a removal process the tool may be configured to allow for the disconnection of the toolPod from the fabricator environment, both for aspects of handling of product substrates and for the connection to utilities of a fabricator including gasses, chemicals, electrical interconnections and communication interconnections to mention a few. The toolPod represents a stand-alone entity that may be shipped from location to location for repair, manufacture, or other purposes.

Process of an Application or “Apps” Model for Tool Design Using the toolPod Construct.

These toolPod constructs represent a novel departure from the state of the art in fabricator tooling where a tool is assembled (sometimes on a fabricator floor) and rests in place until it is decommissioned for that Fabricator. Because there are many similar functions that process tools require to operate, the toolPod for many tool types can be exactly the same with the exception of a region where the different processing may occur. In some other cases, the tool type may require different functions in the toolPod and Chassis like for example the handling of liquid chemicals as an example. Even in toolPod's of this type there may be a large amount of commonality in one type of toolPod to another. This creates an infrastructure where the numbers of common components in processing tools in the industry can be large allowing for economies of scale. Additionally, these toolPods, which may result in economical costs due to the economies of scale mentioned, may provide the ideal infrastructure both for a common definition of tooling solutions for common tasks as well as an economical starting point for the development of new types of tooling or different models of existing types of tooling.

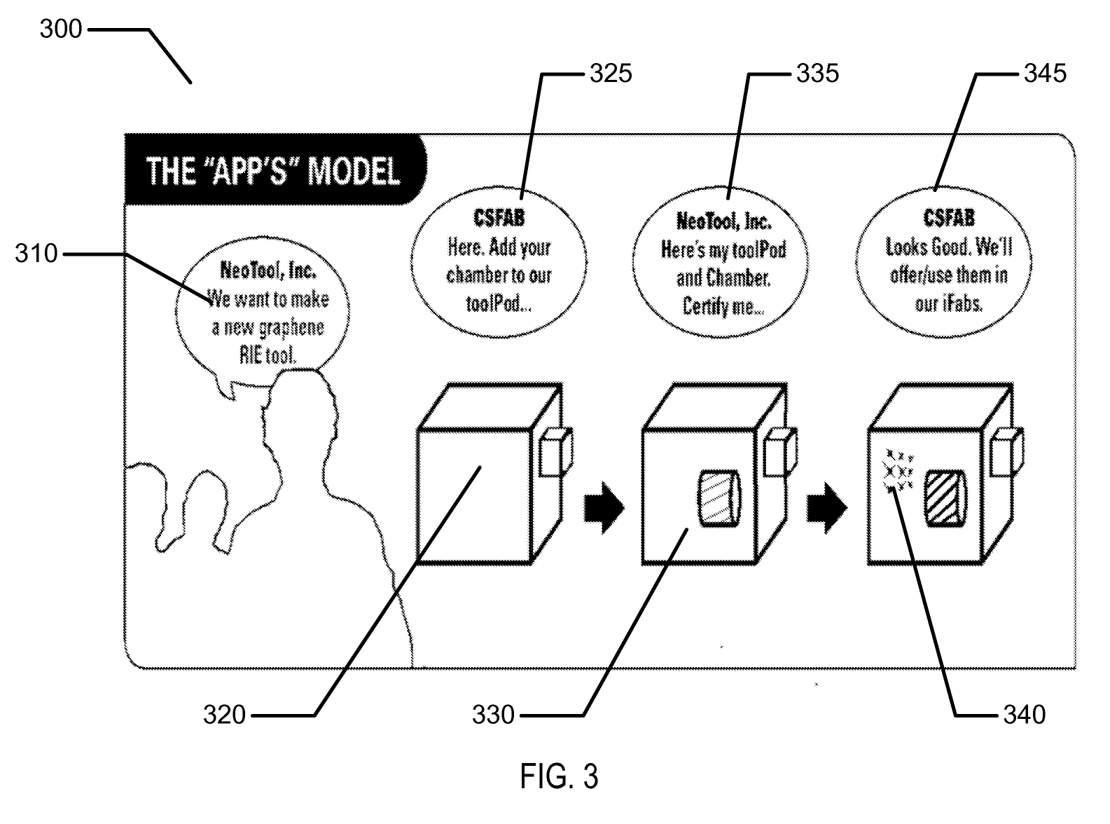

Referring to FIG. 3, a representation to how these aspects of toolPods may allow for a model of tool development that resembles an “Application model” is made. As shown in FIG. 3, item 300, a company or entity may desire to develop a new model of tooling for a purpose. In an entirely exemplary sense, item 310 may represent a desire of a company to develop reactive ion etch (perhaps in some cases for the production of Graphene based electronic devices) tooling for the cleanspace fabricator environment using a standard type of toolPod. In step 320 and 325, a standard toolPod may be provided to the development entity with a significant portion of the tooling infrastructure not related to the exact process definition being defined already. The development entity may add their “reactor” elements to the standard toolPod thus defining a new type of Reactive Ion Etch tooling, as shown in steps 330 and 335. In some embodiments, the thus formed tool may be provided to the entity which provides the toolPods and fabricators related to them in order for the tool to be studied and verified or qualified in terms of the definition of the tooling being useful, safe or acceptable based on other grounds. When the tool is submitted for this qualification or ratification, items 340 and 345, the toolPod and Fab entity may determine that the tooling is good. In some models, the entity may provide its ratification as a service to the development entity. In alternative models, the toolPod and Fab creating entity may offer the newly developed tooling as a product itself. In still alternative models, the toolPod and Fab entity may provide only the toolPod and Chassis themselves or even the designs for the toolPods and Chassis as their portion of the model. There may be numerous different models that represent an application type model for the use of toolPods, Chassis for toolPods, and Cleanspace based Fabricators.

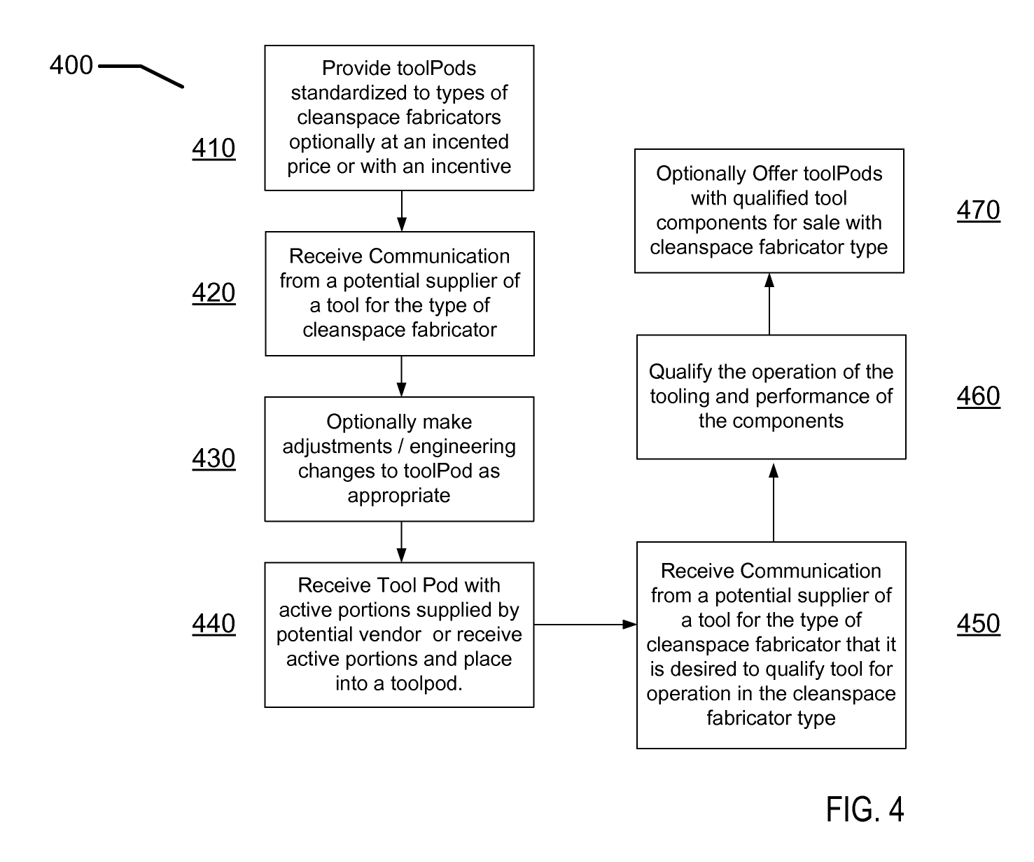

In FIG. 4, item 400, a flow chart presents the process of creating process tools in a cleanspace fabricator environment with toolPods and chassis components. At step 410, a general offering of toolPods to the market place may occur. At some time after, or as an independent starting event a potential manufacturer of a tool may contact a toolPod supplier with the intent to provide a tool incorporated into the toolPod at step 420. Throughout this discussion mention has been made to entities called toolPods which may have their own definitions nevertheless there should be no limitation on the general concepts by the use of this term is intended, and any type of device that has the principal of creating a replaceable environment for processing tools should create additional diversity in the utility of the concepts discussed herein

In some embodiments, the provider of the toolPod at step 430 may interact with the potential supplier to determine if tailoring of the standard toolPod offering is warranted. There may also be a process where the standard toolPods are offered and modifications to add additional function may need to be performed by the potential tool vendor. In some embodiments, changes to the toolPod design may warrant a specialized chassis that mates to the toolPod. In addition there may be some embodiments where multiple toolPod elements mate with a chassis and the alterations may occur to a second toolPod element that mates to a tool Chassis in the standard fabricator definitions.

At step 440, the potential vendor may have designed their tool and created a prototype copy of the tool. In some embodiments they may have tested their process tool in the toolPod by mounting it to a chassis that is external to a fabricator that may be called a test or development stand. When the tool is provided to the toolPod vendor or in equivalent manners to a cleanspace fabricator vendor or operator, it may be requested at step 450 that the tool be tested for various aspects including safety, functionality, interaction with electronic and software systems and various such aspects.

In an alternative embodiment, at 440 the tool vendor may provide to the toolPod vendor or cleanspace fabricator vendor or cleanspace fabricator operator just the portions of the tool that need to be added to a toolPod design to make a functional tool. This tool may then be assembled by the various entities and at step 450 requested to be tested in the aforementioned manners. There may be additional embodiments that are possible with variations in the exact order that various steps are performed in.

In some embodiments the flow may continue to step 460 where the testing will be exhaustive. When a set of tests that are defined as necessary for the qualification of a processing tool are successfully performed then the tool may be considered qualified for various operations that may occur in the cleanspace fabricators that have been described or in variations thereof.

An entity that sells toolPods may offer the newly developed tools for sale. There may be various entities that would or could offer such a product. In a non-limiting exemplary sense the toolPod may be offered for sale by a firm that manufactures Cleanspace fabricators. Or, it may be offered by a firm that offers toolPods. Or, alternatively it may be offered by a firm that specializes in processing tool sales. Another example from other possibilities may include the firm that designed the tool offering the qualified toolPod for sale. In each of these descriptions, examples have been described where qualification has been performed; however there may exist embodiments where the qualification is not performed or some equivalent is performed and each of the previous examples may also have embodiments that derive thereby.

Process of Crowd Sourcing Using Cleanspace Fabricators which are Networked Together in Some Means that Allows Communication of a Need.

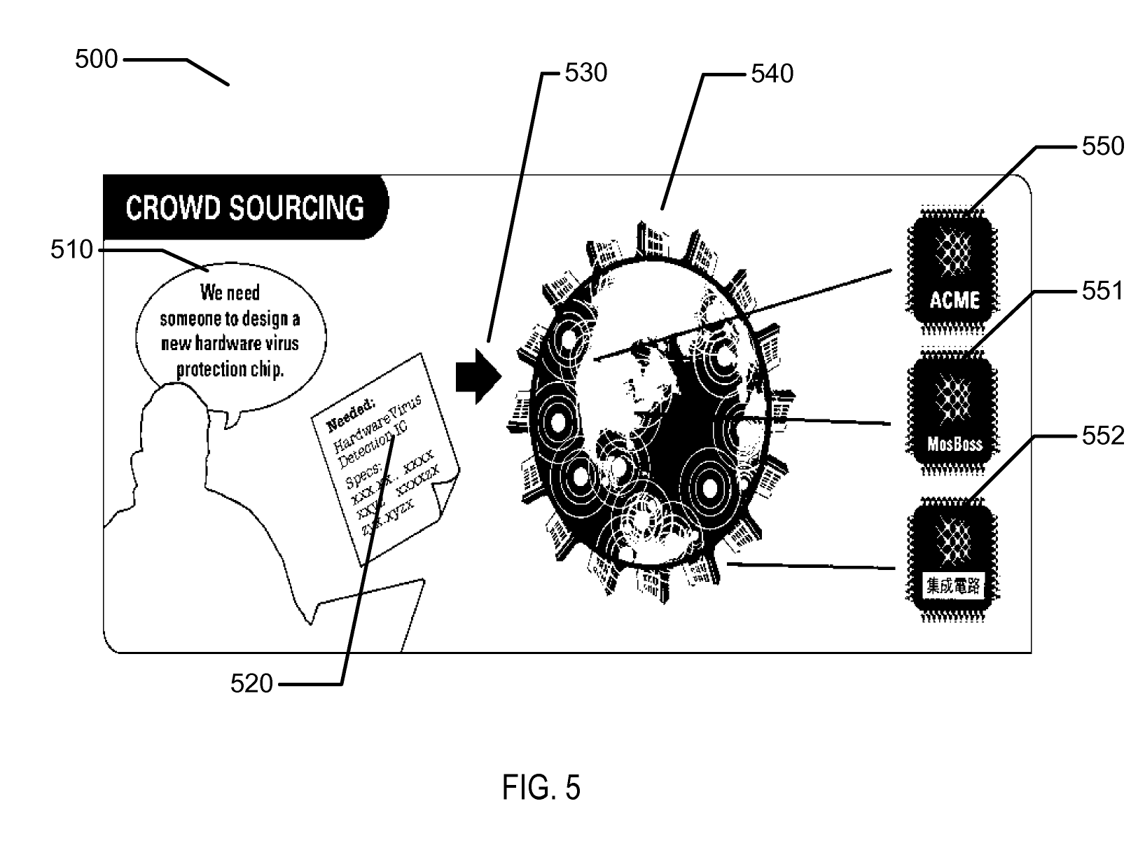

The various types of cleanspace fabricators that have been described or are possible may create collections of fabricators of various scales of manufacturing. In an exemplary sense, small tool fabricators with a focus on small volume manufacturing may define a collection of fabricators which can rapidly and easily create prototype samples of electronic devices. In FIG. 5, item 500 a process where these collections of fabs may be networked together with communication means may be observed. In an example if a large network of small tool small volume fabricators is connected together as is schematically represented as item 540, then a process related to “crowd sourcing” may occur.

At item 510, an entity may express a need for a particular solution to be made. The example entity making this expression may be related to the network in various internal manners including an operator of the network, an owner of the network, an operator of various supply aspects of the network and the like. In alternative embodiments the entity making the expression of a need may be external to the network but have a means of communicating its needs to the network.

At item 520, in some embodiments the expressing entity may formalize their requirements into a set of specification requirements. These specification requirements may be initially included in the expression of the need or follow on in a next step. In some cases these needs may then be communicated by various means, some of which may be described in further detail in following sections, to the network of cleanspace fabricators at step 530.

The network at step 540, thus aware of the need and in some cases the associated specified requirements may assess their capabilities to provide the need. Since there are some embodiments of the inventive art where the sourcing of prototype samples may occur at significantly reduced cost structures it may be a straightforward method for companies, individuals or other entities to create samples in prototype form of material designed to address the communicated need. At steps 550, 551 and 552 a number of entities may have designed solutions and fabricated them in a cleanspace fabricator network. In some of the exemplary cleanspace fabricator networks, large wafer dimensions may occur in others small sized wafers may occur and in still others mixtures may be prevalent. A fabricated prototype may therefore be provided at various terms including at a cost or at no cost from the designer entity through the fabricator or fabricators to the entity expressing a need.

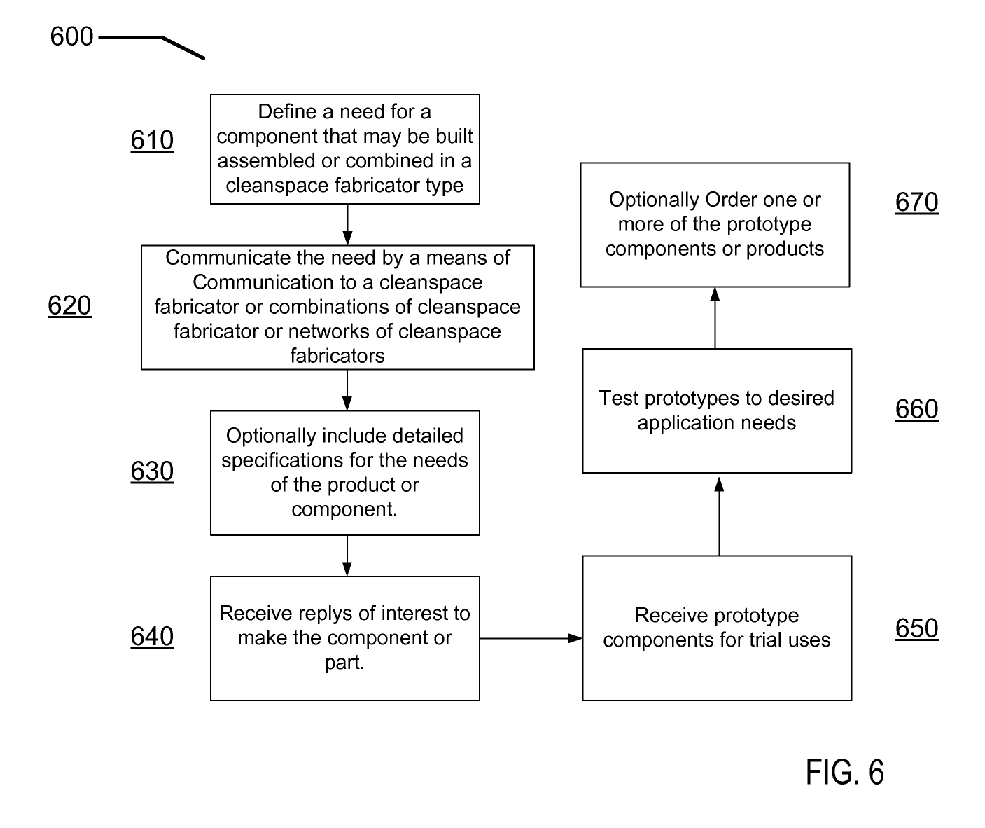

In FIG. 6, item 600, a flow chart of a process that may be considered related to crowd sourcing when using the various types of fabricator networks that may be possible utilizing the inventive art surrounding cleanspace fabricators is depicted. At step 610 an entity expresses a need for a product to be built. This product may be built, assembled or combined in cleanspace type fabricators and some of the cleanspace type fabricators may have elements that have the characteristics of toolPods within them. At step 620, the need may be passed on by various means of communication to fabricators, a network of fabricators or networks of fabricators. At step, 630, in some embodiments an optional step of including specifications and parameters related to the need may be included in the communication. At step 640, in some embodiments there may be a reply communicated from entities interested in designing and building a solution to the need. It may also be possible in some embodiments for this step to be removed from the flow.

Continuing with FIG. 6, item 600 at step 650 an entity may have built prototypes in a cleanspace fabricator of the various networks and have provided a sample prototype to the requesting entity. In step 660, the requesting entity may test a sample provided in one of these method embodiments to the desired performance needs of a device that includes the produced prototype. In a next indicated optional step, item 670, the entity may purchase additional samples or purchase volume quantities from one or more of the suppliers that provided prototype samples. It may be clear that, it is possible that some of the networks include combinations of small volume fabricators that may provide the prototype samples and large volume fabricators that scale up the production after small volume quantities are surpassed.

### Process of Intellectual Property Licensing Using Cleanspace Fabricators.

Cleanspace fabricators, especially for the smaller tool nodes, allow for unique models of licensing of intellectual property. Small volumes of material may be economically manufactured and therefore, use of different predesigned circuit elements may be experimented with. In additional manners, process flows may also be treated as intellectual property that may be licensed through the infrastructure of cleanspace fabricators. There may be also other aspects of forming electronic components that may be able to be licensed as intellectual property including for example methods of packaging and methods of combining different integrated circuits and other components into assembled components to mention a few.

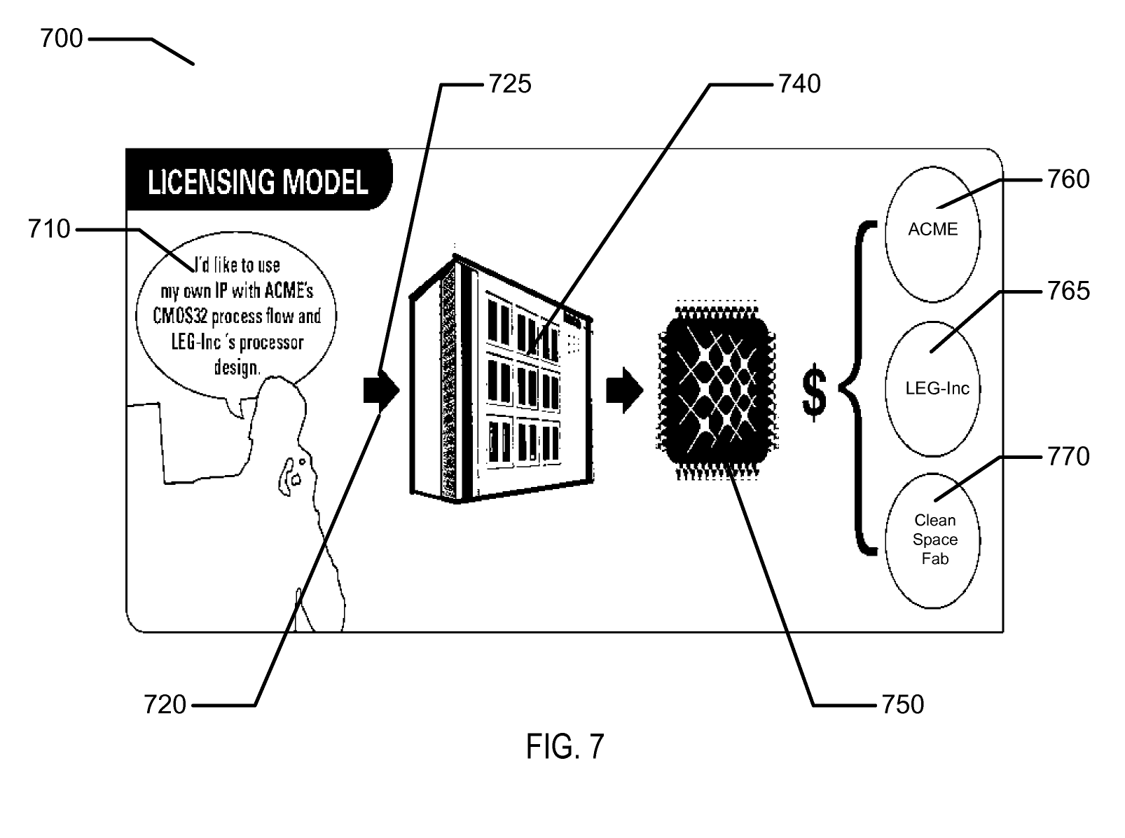

Proceeding to FIG. 7, item 700, an exemplary embodiment for a cleanspace fabricator licensing model may be found. At item 710, a designer or business contact may want to produce a certain amount of production in a novel fashion. In an exemplary sense, the customer may want to build this product using his own design and other intellectual property as well as some standard licensable aspects. In the example at 710, the exemplary use may include using a standard process flow developed by an fictitious firm provided for example, of ACME incorporated, the use of which may be represented as item 720. Another fictitious firm, LEG inc., may be an example of a licensable circuit block design in this case for a licensable processor block, the use of which may be represented as item 725.

Continuing with item 740, the product in example may next be produced in a cleanspace fabricator. The production may include processing wafers to the circuit design using the mentioned wafer processing flow. In addition, the same or similar facilities, 740, may be used to further process, test, assemble and package the product into a finished chip form of the product as shown as item 750. When such a process is followed there may be a flow of royalties and fees that derive from the production of the product, 750. These may be represented as a royalty payment to the exemplary ACME firm for the use of their process modules at 760, and also as a royalty payment to the exemplary LEG firm for the use of their processor design at 765, and also as a payment to the clean space fabricator at item 770.

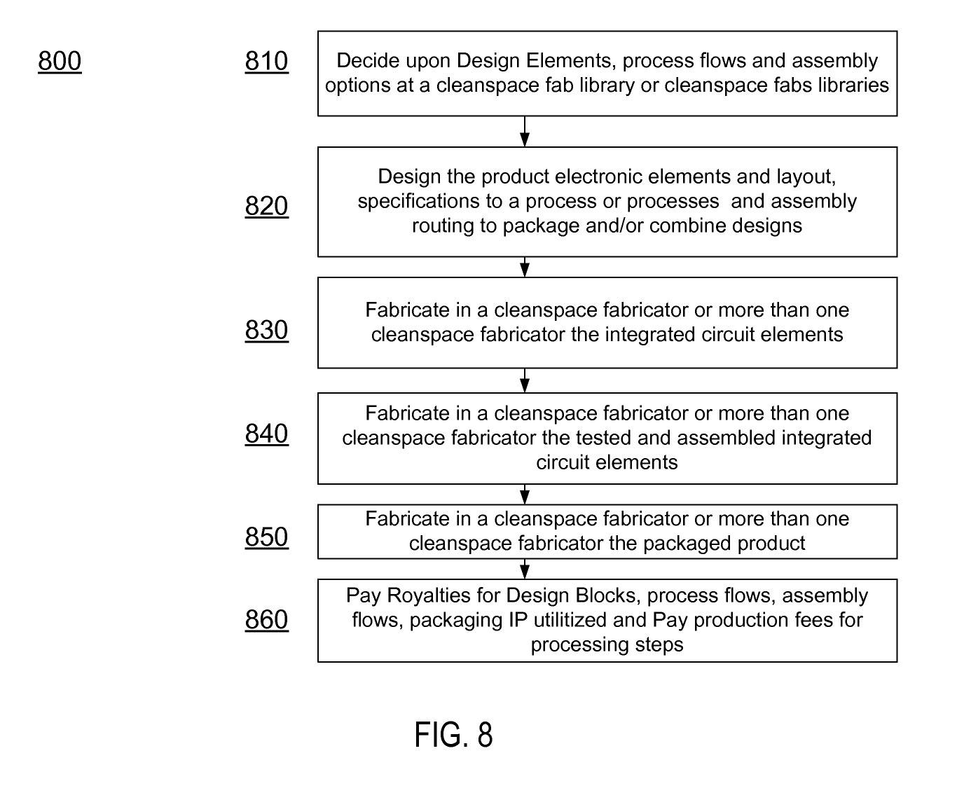

In FIG. 8, item 800, a flow chart of a process that may be considered related to the licensing model when using the various types of fabricator networks that may be possible utilizing the inventive art surrounding cleanspace fabricators is depicted. In step 810 the process of selecting prior art or others to be incorporated into a product may occur as a first step. It may be apparent that in other embodiments the process may be iterative and occur in loops of various kinds. Nevertheless, there may be associated with each cleanspace fabricator or each network of cleanspace fabricators a construct which may be called a library or a combination or network of libraries that relate to the aspects of the product which may be licensed. Some of the types of elements that may exist in the library might be the design layout and “mask making” information associated with certain circuit blocks. Additional types of elements in the library may include process flows that call out the ordering of process tools and associated process specifications that may occur on the tools related to the product. Additionally, test related elements may be found as well as process flows and design aspects for types of packaging. From the flow of making substrates themselves to the output of a packaged product perhaps including attached die on substrates with attached peripheral components a great many aspects of the product design may be included in a library that links capabilities at a fab to user accessible blocks to call out such capabilities, in some cases even including the combination of processing at multiple fabricator locations with their individual networked libraries.

After an initial selection of blocks to be licensed in the production flow of the product, a design step may occur at item 820. In this design step various licensed items may be incorporate as well as the addition of new proprietary design aspects which may be in circuit design, layout, process step details, assembly and packaging. There may be numerous other types of design aspects like the incorporation of MEMS devices and power device fabrication into the flow as a few non limiting examples.

At step 830, the cleanspace fabricator or fabricators are used to process a substrate into one or more of the integrated circuit elements. Continuing with the process flow into step 840, this fabricated circuit element or these fabricated circuit elements may be tested and then assembled into integrated components of various kinds. Next in step 850, the integrated components may be assembled into a packaged product which may be performed either at a wafer level of assembly/packaging or at the component level itself. In this exemplary process flow, the finishing of the production, at 860, may trigger an even where the royalties for the various elements be they design blocks, process flows, assembly flows and packaging aspects are calculated by either a person or an automated system and then a payment scheme may occur. In addition, a payment or billing process may occur for the billing of the processing steps which occur within or in combination of steps within a cleanspace fabricator.

### Methods of Communication Between Cleanspace Fabricators and Other Entities.

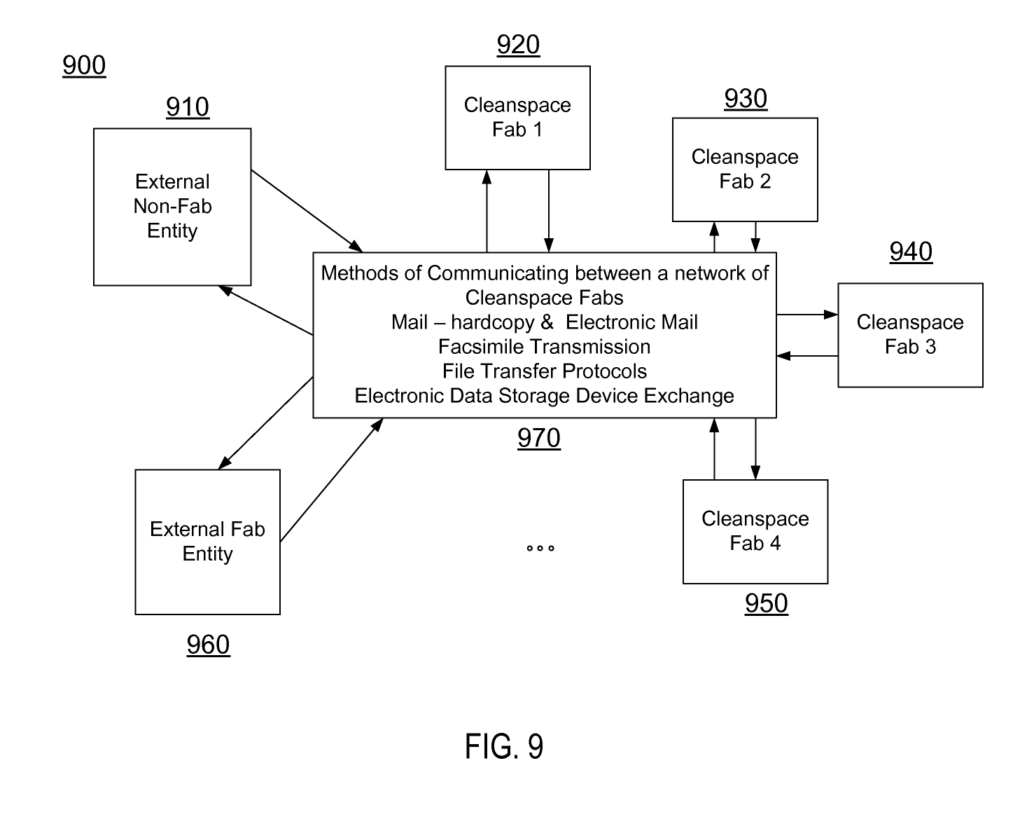

Proceeding to FIG. 9, item 900, a depiction of the methods of communication between a cleanspace fab and other entities is portrayed. In the example, a cleanspace fab may be represented by item 920. The arrows into and out of the 920 may represent communication events into and out of the fabricator entity. In 970 some exemplary communication modes may be observed. In a non-limiting sense amongst the potential modes of communication are included forms of mail both electronic and hardcopy. Also information may be exchanged by telephone based protocols including for example facsimile transmissions. In addition, Ethernet and internet forms of communications may be useful for the exchange of data files using various types of file transfer protocols and other means of electronic data storage exchange which may include both physical transfer of devices and wired/wireless electronic forms of communication.

These various forms of communications as shown in 970 may be useful for communications between the various demonstrated cleanspace fabricators as shown in items 920, 930, 940 and 950. As well, any of these cleanspace fabricators may receive communications from external entities. Some examples of such external entities may include for example item 960 which represents other Fab (which is meant to include both semiconductor fabs and assembly and test fabs.) External entities may also include entities which are non-fab entities. For example, a fabless customer/designer may be a type of entity represented in item 910. Certain aspects of the communication paths have been shown in FIG. 9 include a number of cleanspace fabricators, a few example means of communication and data storage and types of external fabs. The diversity of communication means and parties to the communication is provided for example and should not limit the generality of the concepts herein.

### Processes for the Production of Large Volumes of Production Using Smaller Wafer Sized Tools.

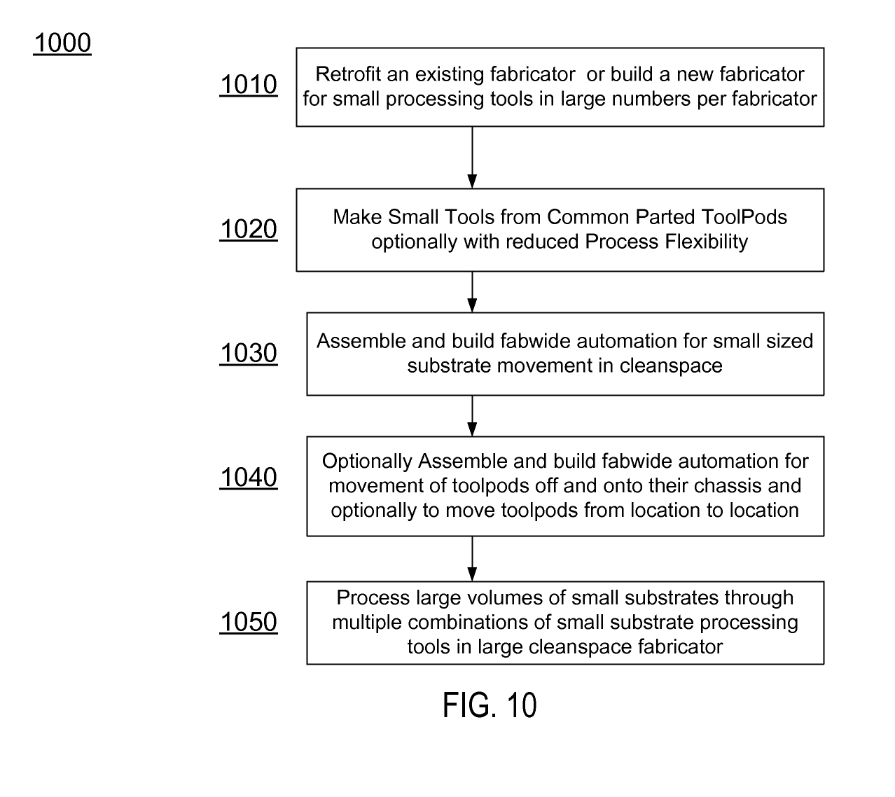

In much of the discussion in this and previous disclosure by this inventor there has been description of the innovations related to cleanspace fabricators directly and also to the innovations that come from this novel environment which tend to open up economic models for the production of small levels of product. However, referring to FIG. 10, item 1000, there may be innovative models that utilize the cleanspace and cleanspace derived innovations in novel manners to address large scale production volumes.

At step 1010, a fabricator with a large footprint is deployed. In some embodiments this may entail building a new facility in others it may entail retrofitting portions of an existing fabricator or an entire existing fabricator. The resulting fabricator will have cleanspace regions that support the movement of large amounts of small substrate pieces from process tool to process tool. Furthermore, the numbers of locations for processing tools will be very large in these resulting fabricators.

Proceeding to step 1020, the small tools that will populate the large volume fabricator will be produced. In some embodiments, these tools will use the infrastructure of the toolPod and chassis that is important to small volume fabricator models. An additional diversity may come from some additional changes that may be made to these tool designs because of the fact that they may be used in large collections. In smaller collections of processing tools either related to large (greater than 8 inch) wafer size plants with produce large volumes of products or for small wafer sizes where smaller number of tools allow for an infrastructure that economically supports small volumes of production, the processing tools in these models need to be able to be flexible to perform a variety of processing conditions. For example, gas flows may need to be flexible to different flow rates. And, there may be a need to have multiple different gasses connected to the tool where only a subset are used for any particular process. This type of flexibility can be found in most tool types where plasma conditions and gasses are programmable and flexible, implant conditions are programmable and flexible; and in a more general perspective most tools have degrees of flexibility which increase the cost per tool. In a large volume model, a particular process tool can be simplified to support a single processing condition in the process flow. This may improve economics of the processing tool and in some embodiments allow for a simplified process tool that may in some cases be used and then not repaired, but merely replaced. Not all embodiments require the tool model to be this novel compared to current state of the art, however, the combination of large numbers may create novel fabricator entities.

Continuing to item 1030, the large volume fabricators will be fitted so that the cleanspace regions have automation to move small substrates around within them. In some embodiments, a collection of very fast robotic elements will define the type of fab-wide automation. In other embodiments, there may be an infrastructure that combines large numbers of automatic robots which move through the cleanspace in concerted fashion. There may be numerous manners of automating the large volume fabricators that are processing small substrates.

Next continuing to item 1040, another optional aspect of the fabricator design that may be more economically justified for large volume fabricators using small tools than for other fab models is the configuring the fabricator for automation of tool change events. A cleanspace fabricator can in some embodiments have the nature where its tools are peripherally located. In small volume fabricators this allows for technicians to easily perform functions to change the tools out of the factory one at a time without interrupting the function of the rest of the factory. However, it is also possible to equip the factory with automation that performs the tool change out in an automatic fashion as well. In this model the space on the other side of the processing tools from the cleanspace would also have robots of various kinds that swap out tools. There may be numerous types of cleanspace fabricator design types that enable this type of automation.

Proceeding to item 1050, the assembled tools and automation in a type of cleanspace fabricators are used to produce product. As mentioned factories configured for large volumes of production may have very large numbers of tools deployed in manners consistent with the cleanspace fabricator type. In some cases these processing tools may be simplified to perform a single type of processing step within a limited processing window. This may allow for a number of different models of the production flow. It may be possible for example to divide the processing fab into regions, that are either physically defined or through the use of computers, electronically defined from combinations of select tools regardless of where they physical residing. In embodiments where the tools are segregated into regions of one type or another a particular process flow may be performed that only flows through the region itself. In an alternative scheme the processing of wafers may, under computer control, allow for wafers to progress in processing through the fabricator where any step may be processed with any tool capable of performing the processing step. There may be a very large diversity of manners of producing product in such an environment.

### Processes for Qualifying a Design in Multiple Process Flows in a Cleanspace Fabricator Network.

In a state of the art fabricator, it may be typical that a number of process flows may be operant at a certain time. However, due to the nature and economics of fabricators it may be common that each of those flows represent a one of a kind processing selection for a particular generation of technology and its offspring. Thus, for example a factory may have a 45 nm generation with some different modifications in certain areas like for example, the type of substrate or the type and number of gate oxide features, or the type and number of metal levels to mention a few examples. It is however rare to have multiple process flows for the same technology generation. The infrastructure of a small tool, small volume focused fabricator actually enables the utilization of multiple process flows of the same technology generation. In a non-limiting example, there could be for example three different 45 nm process flows that closely resemble process flows in different Foundry companies. In such a case, the presence of these different flows allows the user to process his designs in a parallel fashion through the different flows. In some embodiments such processing may search for the best performance of the design amongst the choices. In other embodiments the flexibility may allow for multiple paths in sourcing the product when the customer demand of the product exceeds a small volume level and the product is sourced from foundries.

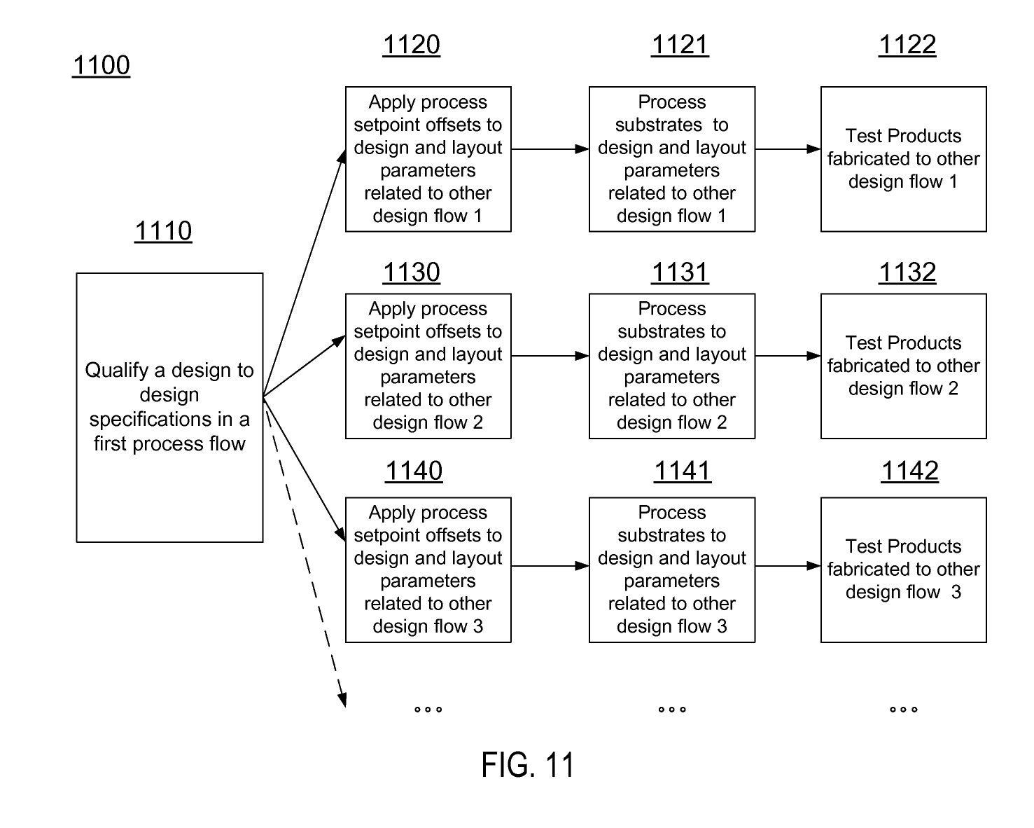

At step 1110, the general process may start with having a design that has been successfully produced by various means in a first process flow type. The designers of the product in the process shown in item 1100 of FIG. 11 may decide to produce prototypes of the product in the different flow options that exist. In FIG. 11, three exemplary flows are shown in a parallel fashion for three different results. In steps 1120, 1130 and 1140 respectively the same type of process step occurs in different manners for three other flows indicated as flow 1, flow 2 and flow 3 respectively. In these steps the design parameters both from a design aspect and a layout perspective are adjusted in manners appropriate for the different flows 1, 2 and 3. In a next series of parallel steps, 1121, 1131 and 1141, the substrates are then processed through the cleanspace fabricator to the different flow conditions relating to flows 1, 2 and 3 respectively. Finally in steps 1122, 1132 and 1142 in a parallel perspective each of the substrates that has been produced may be tested both for process controls relating to the individual process flows 1,2 and 3 and/or to product related test that are defined for the product mentioned in step 1110.

### Operating Maintenance Facilities at an External Location

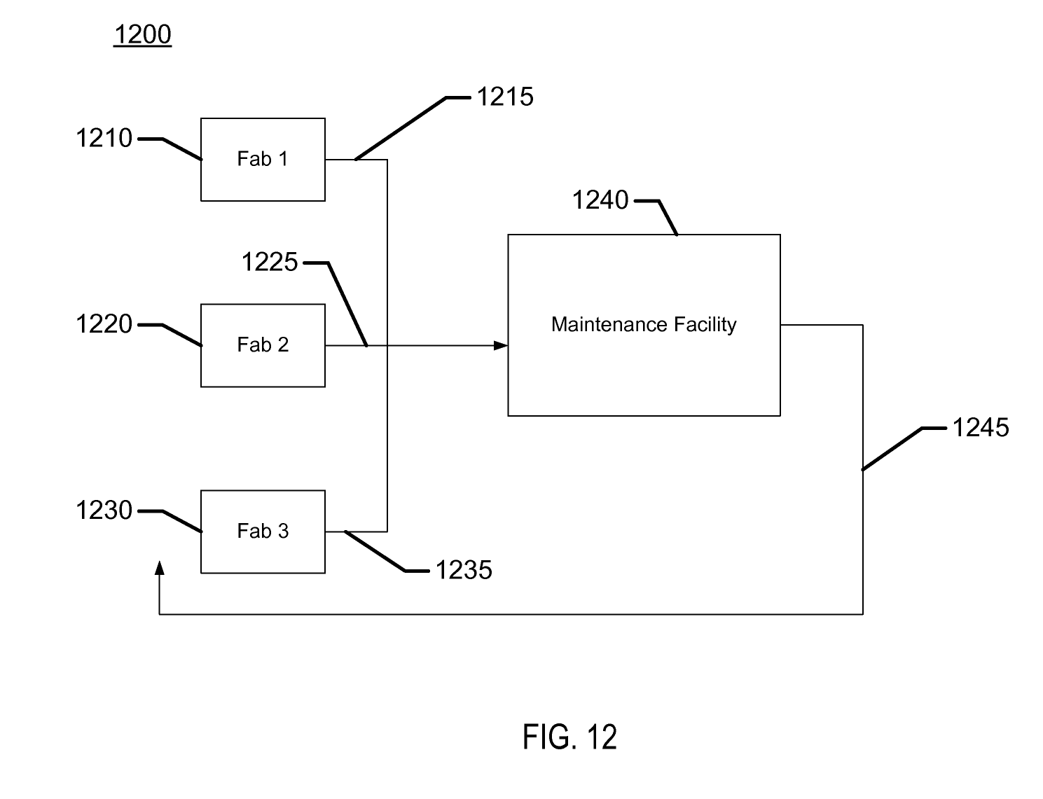

State of the art processing fabricators have by their very nature a single mode type for maintenance of processing tools. In the perspective being addressed at this point, these tools are maintained in the cleanroom at a location where they have been placed and installed for the duration of their useful lives. The cleanspace fabricator with toolPods and chassis type implementations creates a different type of model where tools are removed and replaced routinely. This novel ability creates different models relating to tool maintenance. Proceeding to FIG. 12, item 1200 a model for maintaining tools in a system of cleanspace fabricators is shown. Items 1210, 1220 and 1230 depict exemplary embodiments of cleanspace fabricators that contain processing tools that may be removed from the factory and replaced. In the model a tool from each of the fabricators may be removed from Fab1 in step 1215 or in Fab 2 in step 1225 or alternatively in step 1235 from Fab 3. These tools may in these steps be shipped to a Maintenance facility shown as item 1240. In some embodiments, the fabricators of items 1210, 1220 and 1230 may be located at or near a common central location and the location of the Maintenance facility 1240 may be also located on the same central location. In an alternative extreme, the three exemplary fabs may be located at different locations over the world, including for example on three different continents. In this case the transportation involved in steps 1215, 1225 and 1235 from the fabs to the maintenance facility may include truck, rail, plane, and boat modes and may include combinations of these modes to get the tools to and from the maintenance facility. Step 1245, depicts the process of moving or transporting repaired tools which have been repaired in the maintenance facility 1240 and moving them back to the fabs 1210, 1220 and 1230. In some embodiments a process tool in this flow may be “owned” or associated with a particular fab and therefore the same tool that moves out of fab 1, item 1210 in a step 1215 for example may move back to item 1210 fab 1 after repair in facility 1240. In other embodiments, the repaired tools may be generically available to fab networks and after repair at facility 1240 may be sent, for example to whichever of item 1210, 1220 and 1230 is needed.

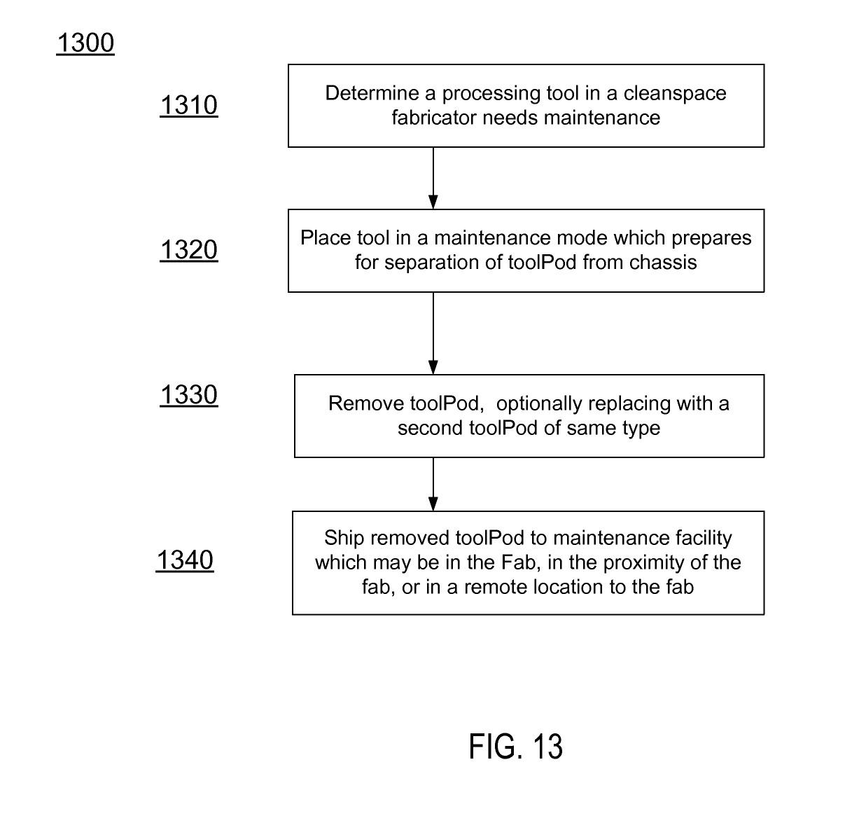

In a related sense, proceeding to FIG. 13, item 1300 a method for repairing tools in a fabricator using the approach from FIG. 12 may be found. In a step 1310 within one of the fabricators a step may be performed to determine that a processing tool needs maintenance. Such a step may involve system counters that monitor the number of processing steps that are performed on the tool and this counter thus triggering a maintenance event. Alternatively there may be quality checks that are performed on test or monitor wafers that demonstrate that a tool needs replacement. In some embodiments there may be feedback from tests performed on substrates that have been processed through the process tool that warrant the tool being maintained. There may be numerous reasons for at tool to be identified as needing maintenance.

Proceeding to step 1320, the tool that has been determined to need maintenance may be deactivated from its processing role and placed in some kind of maintenance mode. In some embodiments a fab-wide computer based automation system may communicate in a variety of manners including wired and wireless communication protocols to instruct the process tool to assume a maintenance mode. In alternative embodiments a person may receive information that the processing tool needs to be replaced and they may direct the tool to enter a new state, perhaps called a maintenance state, which allows for the removal of the toolPod from its chassis.

Proceeding to step 1330, the tool that has been placed into its maintenance mode by some means may next be removed from the fabricator. As mentioned in previous sections this removal may be effected by people or in some embodiments there may be automation that performs the removal. In either event, after the tool is removed there may be an optional step where a replacement tool is immediately replaced upon the tool chassis and with other processing steps made to be an active tool choice in the fabricator.

Next in step 1340, actions are next performed on the toolPods removed from the factory. The toolPod in need of maintenance will next be transported by some means from the fab to the repair facility.

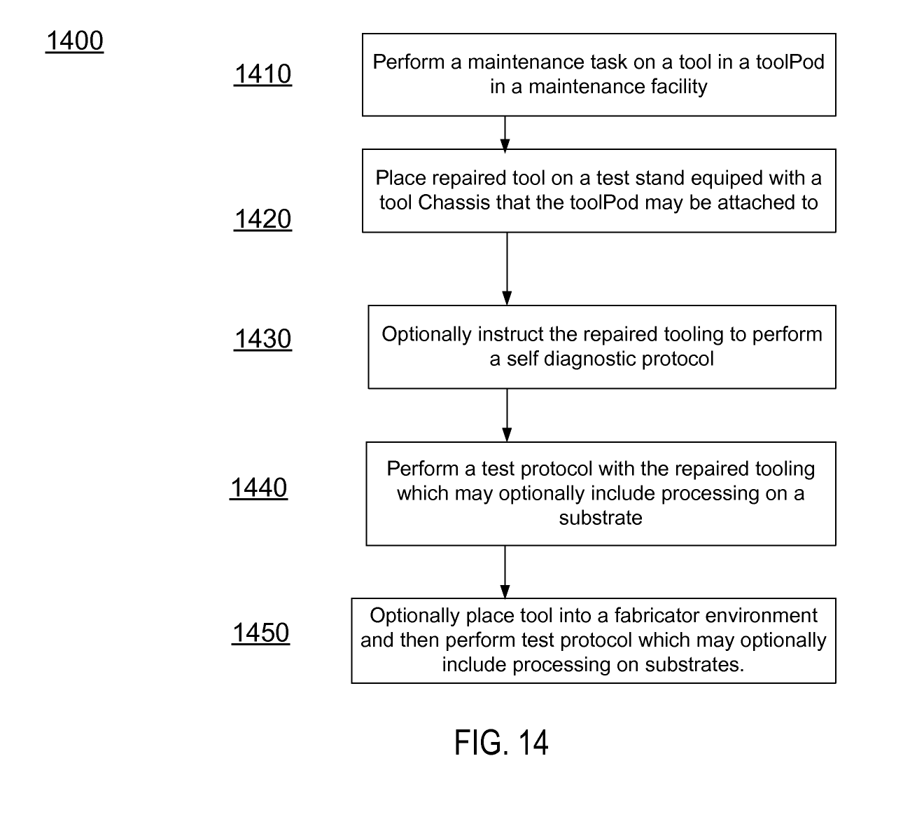

Proceeding to FIG. 14, item 1400 an exemplary method may be associated with the steps that may occur within the repair facility identified as item 1240 in FIG. 12. At step 1410, the tool in need of repair may have maintenance tasks performed upon it at the maintenance facility. In some embodiments the maintenance facility may include a large cleanroom in which the staff function to perform the maintenance.

After performing the appropriate maintenance task or tasks on the tool in the toolPod a next step may now follow in step 1420. At this step, the repaired tool may next be placed upon a test stand. In some embodiments, the test stand may exactly replicate the connections that occur on the chassis that would be located in the fabricator to attach to the toolPod in question. In other embodiments a different perhaps more generic connection to the toolPod may be made with a test stand. The test stand may include functions like providing vacuum to the toolPod, providing electrical power, providing signal communication, providing gas flows, liquid flows, chemical exhaustion of various kinds and many of the functions that are commonly used by processing tools.

Proceeding to step 1430, in some embodiments the toolPod upon the test stand may have an ability to conduct a self-testing protocol. There may be many algorithms that are consistent with testing the function of a particular tool in manners that may be performed in an automated function. For example, one of many such possible functions may be the testing of the toolPod for its vacuum integrity. Through various sensors and automation steps the tool may have a vacuum formed within itself and then that portion of the tooling may be isolated from the evacuation portions of the test stand. Thereafter, the pressure in the tool may be monitored with sensors that exist either in the toolPod itself or on the test stand. Any of a number of standard type tests that particular tools may be receive may be algorithmically programmed into the toolPod and/or the test stand.

In step 1440, a general test protocol may be performed on the toolPod that has been repaired. In some cases, the types of tests mentioned in the step 1430 may be manually performed for example. However other tests may also be performed that relate to handling of substrates, processing of example substrates and production of substrates which may be evaluated for controls on the quality of the tool in question. A non-limiting example of such a test may include receiving a monitor wafer into the toolPod through a standard toolport of the tool and then cycling the monitor wafer through various portions of the toolPod under various process conditions which may simulate actual processing. Thereafter the monitor wafer may be cycled out of the toolPod and a measurement of the levels of particulate matter that has been deposited upon the monitor wafer may be made.

There may be more sophisticated testing which is performed on the tool to test and assure its capability to actually perform one or more actual processes within it. In step 1450 an optional step is depicted that represents testing the tool under actual performance conditions. In some embodiments, the tool may be transported to a cleanspace fabricator, installed in the fabricator and then used to process substrates in a manner that allows for the process results to be assured and verified for the tool before it is shipped back to a production related cleanspace fabricator.

Processes for operations of New Research and Development in Multiple Locations.

The novel aspects of the cleanspace fabricator with toolPod/Chassis innovations allows for new methods of performing high technology production functions that are particularly useful for activities of small volume. One family of processes that by its very nature is of small volume is those processes relating to research and development. There can be very many different types of research and development processes that can occur. For example, the process of generating and evaluating new types of semiconductor processing may be considered where different materials are used or different manners of processing the materials may be involved to mention a first example.

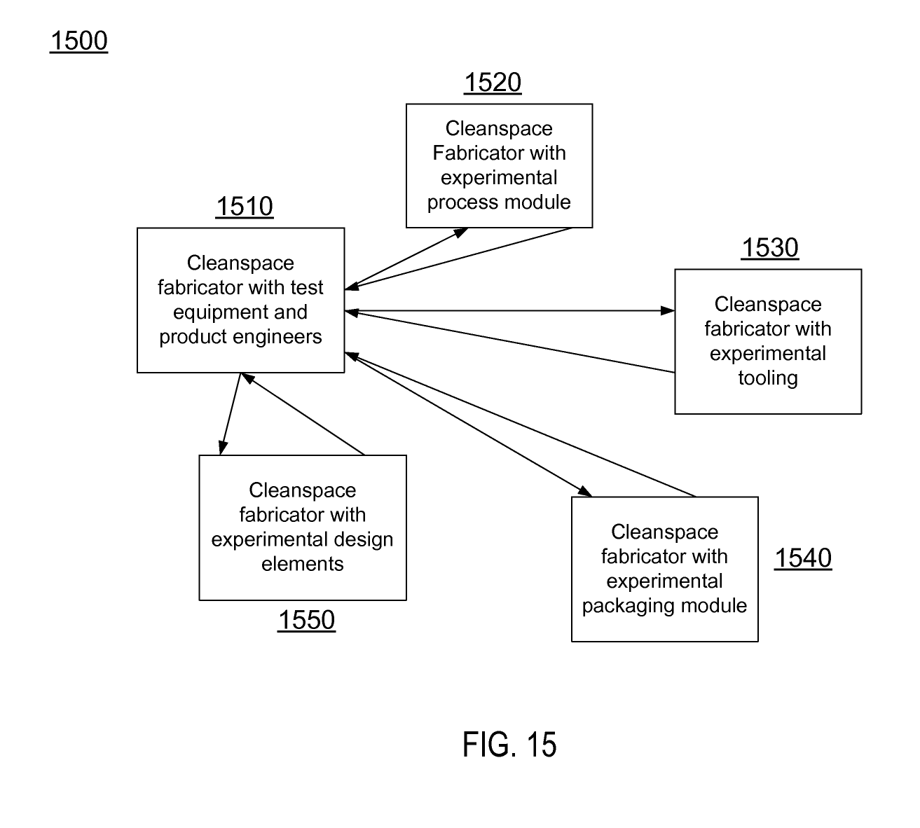

Proceeding to FIG. 15, item 1500 a depiction of a variety of different research and development type processing is made. An additional aspect may or may not be involved in the processing described in FIG. 15. In some embodiments, a research and development aspect may be performed in a particular cleanspace fabricator and then additional processing may occur in an alternative such processor. In other embodiments, it may be possible that research and development activities may be performed merely in one of the facilities depicted as a box in FIG. 15. Alternatively, some or all of the boxes in FIG. 15 may represent activities within a single cleanspace fabricator which is configured to allow all the activities to occur.

For illustration purposes however, we may describe a case where each of the boxes in FIG. 15 may represent a separate cleanspace fabricator which performs some novel function related to research and development. In a starting fabricator shown as item 1510, a cleanspace fabricator may be formed to include standard types of processing tools, processing flows and other standard aspects. At this first facility may be located a particular set of product engineers who are performing research and development activities for a particular product type where they have developed their own test equipment that correctly match the new products that are experimenting with. In some embodiments of the type now being described such a fabricator may be considered a main location of the research and development activity for this novel product. Substrates may be processed in this facility represented by item 1510. In some cases, however, there may be a need to perform experimental processing steps either with new materials or new methods of processing materials. Another cleanspace fabricator, depicted as item 1520, may have developed capabilities to perform these processes or utilize these new materials. Thus substrates may be routed from facility 1510 to 1520 and back to produce experimental versions of product with these new processing characteristics.

In an alternative or perhaps supplementary aspect, there may be a need of performing experimental processing with the substrates of location 1510 in another facility where there is different experimental tooling. As shown by item 1530, a different facility may exist where found amongst the tooling within the facility is novel tooling. Either for the purposes of the research and development of fabricator 1510 or the purposes of fabricator 1530 or both substrates may be processed in both 1510 and 1530 using the experimental tooling as another example of research and development models potentially operant with the cleanspace and toolPod models of fabricators.

Continuing with alternative or supplementary examples, a different type of research and development may involve either processes, materials, or components relating to the packaging of products. In an example the fabricator of item 1540 may have developed and/or have experience performing a particular assembly step upon substrates. In some other embodiments they may also have the ability of using particular materials or package designs in relationship to the substrates being processed in fabricator 1510. Again, substrates may be moved from 1510 to 1540 and back in an example of the types of processes that are possible with the cleanspace and toolPod fabricator models herein.

Yet another type of research and development activity that may be considered in this framework relates to the development of experimental designs. In item 1550 an exemplary fabricator may have developed particular design elements that they are expert in. In some models these new designs may become intellectual products that are licensed as mentioned earlier. In some embodiments, however, it may be that the design elements are not yet released in such a manner for general use, or that the owners prefer for small volumes to produce the new designs themselves. Referring to FIG. 15, again substrates may flow from fabricator 1510 to and back from the fabricator indicated by item 1550.

From a matter of generality, examples have been made with reference to FIG. 15 that relate to each of the numbered boxes representing a different fabricator. It is reminded that such an example was just one of a number of possibilities. For example, all of the boxes may represent functions which reside in a single fabricator entity or any combination of the boxes may reside in multiple fabricators and still represent art within the scope of the inventions herein.

Operating Collections of Cleanspace Fabricator Based Innovations for Configurations that are Less than Full Factory Scale for Research and Development Processes

A number of discussions have been made relating to the operations of fabricators of the cleanspace fabricator type when the additional innovation of the toolPod and tool chassis concept may also be involved. The elements of these innovations provide a number of novel methods relating to fabrication. In general, a number of these discussions related to full processing entities; that is entities that can fully process a substrate to a desired end product need. It may be apparent, but is important to note that in some embodiments consistent with the inventive art herein, entities may actually be defined by subsets of the processing tools that would be required to fully process substrates into a product. The various models may be interpreted to relate both to full processing fabricators and partial processing entities as well.

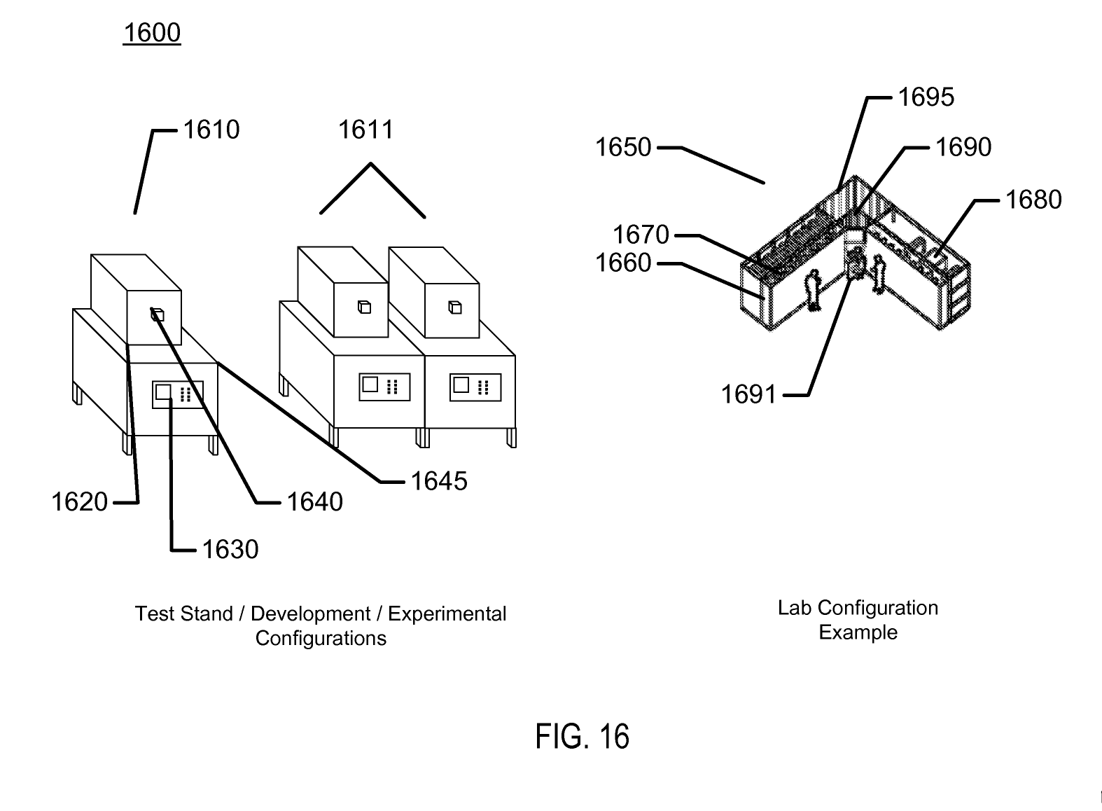

In some examples, processing entities utilizing the inventive art while not defining fabricators per se are shown in FIG. 16, item 1600. There may be various methods related to combinations of the type in FIG. 16. In an extreme example a combination of a tool pod and a test stand may be found as item 1610. This type of combination was referred to in the discussion relating to FIG. 14, item 1420 as an example. A test stand, item 1645, may have the ability of correctly mating with a toolPod, 1640 at the point identified as item 1620. When the toolPod is connected to the test stand in this manner, there may be means for the toolPod control systems to interface with those of the test stand, which may be identified as item 1630. There may be numerous purposes for such an entity as item 1610. As previously mentioned the combination may provide a means of testing a toolpod that has been subjected to a maintenance activity. In addition, however, the combination may provide an ideal configuration to support tool developers to develop and test new tooling concepts. Although an isolated toolPod and test stand of this kind may not be able to produce substrates as a full factory would, it could nevertheless be very useful for developing toolPod entities that after their development could be tested in actual fabricator environments. Another type of use for the toolPod and test stand concept of item 1610 may be in laboratory type settings where the research and development into new materials or the fundamental scientific aspects of a processing step may only require a single processing environment for the process need.

As shown in item 1611, combinations of toolPods and test stands are also consistent with the inventive art herein. In some embodiments, combinations of similar test stand and toolPods may be formed. Alternatively, the combination may involve different types of either toolPods and/or test stands.

Another type of configuration may be envisioned by the item depicted as 1650. In this exemplary configuration of a subset of tools that would typically be found in an entire fabricator a construct that might be called a lab configuration may be formed. In some embodiments a cleanspace may be formed in similar manners that have been defined and may be represented as item 1660. Processing tools may have toolports, item 1670, as typically would occur in cleanspace fabricators. And, there may be a number of processing tools an example of which may be item 1680. The total number of tools may be less than that to form a product, but more than isolated toolPod/tool stand type configurations. In some embodiments there may only be one level of tooling in such an entity as depicted in FIG. 1650. Alternatively, there may be multiple levels in configurations that will still not reflect a full processing fabricator that are consistent with such an entity. The various aspects of processes for research and development that have been discussed may alternatively relate to these types of entities as well.

As describe on FIG. 16, item 1650 may represent an exemplary laboratory configuration that uses the concepts of a cleanspace fabricator and the concept of toolPods to form a smaller entity for performing research and development type activities. In the lab configuration of item 1650, there may be another region labeled as 1690 where substrates of various kinds are stored and also placed and removed into the environment. In some embodiments an operator such as one shown as item 1691 may place or remove the substrates. And additionally in item 1695 there may be a location within the lab configuration where various utility aspects and various chemicals, materials and gasses may be stored and handled for the operation of the entity 1650.

### Glossary of Selected Terms

Reference may have been made to different aspects of some preferred embodiments of the invention, examples of which are illustrated in the accompanying drawings. A Glossary of Selected Terms is included now at the end of this Detailed Description.
Air receiving wall: a boundary wall of a cleanspace that receives air flow from the cleanspace.
Air source wall: a boundary wall of a cleanspace that is a source of clean airflow into the cleanspace.
Annular: The space defined by the bounding of an area between two closed shapes one of which is internal to the other.
Automation: The techniques and equipment used to achieve automatic operation, control or transportation.
Ballroom: A large open cleanroom space devoid in large part of support beams and walls wherein tools, equipment, operators and production materials reside.
Batches: A collection of multiple substrates to be handled or processed together as an entity
Boundaries: A border or limit between two distinct spaces—in most cases herein as between two regions with different air particulate cleanliness levels.
Circular: A shape that is or nearly approximates a circle.
Clean: A state of being free from dirt, stain, or impurities—in most cases herein referring to the state of low airborne levels of particulate matter and gaseous forms of contamination.
Cleanspace (or equivalently Clean Space): A volume of air, separated by boundaries from ambient air spaces, that is clean.
Cleanspace, Primary: A cleanspace whose function, perhaps among other functions, is the transport of jobs between tools.
Cleanspace, Secondary: A cleanspace in which jobs are not transported but which exists for other functions, for example as where tool bodies may be located.
Cleanroom: A cleanspace where the boundaries are formed into the typical aspects of a room, with walls, a ceiling and a floor.
Conductive Connection: a joining of two entities which are capable of conducting electrical current with the resulting characteristics of metallic or semiconductive or relatively low resistivity materials.
Conductive Contact: a location on an electrical device or package having the function of providing a Conductive Surface to which a Conductive Connection may be made with another device, wire or electrically conductive entity.
Conductive Surface: a surface region capable of forming a conductive connection through which electrical current flow may occur consistent with the nature of a conductive connection.
Core: A segmented region of a standard cleanroom that is maintained at a different clean level. A typical use of a core is for locating the processing tools.
Ducting: Enclosed passages or channels for conveying a substance, especially a liquid or gas—typically herein for the conveyance of air.

Envelope: An enclosing structure typically forming an outer boundary of a cleanspace.
Fab (or fabricator): An entity made up of tools, facilities and a cleanspace that is used to process substrates.
Fit up: The process of installing into a new clean room the processing tools and automation it is designed to contain.
Flange: A protruding rim, edge, rib, or collar, used to strengthen an object, hold it in place, or attach it to another object. Typically herein, also to seal the region around the attachment.
Folding: A process of adding or changing curvature.
HEPA: An acronym standing for high-efficiency particulate air. Used to define the type of filtration systems used to clean air.
Horizontal: A direction that is, or is close to being, perpendicular to the direction of gravitational force.
Job: A collection of substrates or a single substrate that is identified as a processing unit in a fab. This unit being relevant to transportation from one processing tool to another.
Logistics: A name for the general steps involved in transporting a job from one processing step to the next. Logistics can also encompass defining the correct tooling to perform a processing step and the scheduling of a processing step.
Maintenance Process: A series of steps that constitute the repair or retrofit of a tool or a toolPod. The steps may include aspects of disassembly, assembly, calibration, component replacement or repair, component inter-alignment, or other such actions which restore, improve or insure the continued operation of a tool or a toolPod
Multifaced: A shape having multiple faces or edges.
Nonsegmented Space: A space enclosed within a continuous external boundary, where any point on the external boundary can be connected by a straight line to any other point on the external boundary and such connecting line would not need to cross the external boundary defining the space.
Perforated: Having holes or penetrations through a surface region. Herein, said penetrations allowing air to flow through the surface.
Peripheral: Of, or relating to, a periphery.
Periphery: With respect to a cleanspace, refers to a location that is on or near a boundary wall of such cleanspace. A tool located at the periphery of a primary cleanspace can have its body at any one of the following three positions relative to a boundary wall of the primary cleanspace: (i) all of the body can be located on the side of the boundary wall that is outside the primary cleanspace, (ii) the tool body can intersect the boundary wall or (iii) all of the tool body can be located on the side of the boundary wall that is inside the primary cleanspace. For all three of these positions, the tool's port is inside the primary cleanspace. For positions (i) or (iii), the tool body is adjacent to, or near, the boundary wall, with nearness being a term relative to the overall dimensions of the primary cleanspace.
Planar: Having a shape approximating the characteristics of a plane.
Plane: A surface containing all the straight lines that connect any two points on it.
Polygonal: Having the shape of a closed figure bounded by three or more line segments
Process: A series of operations performed in the making or treatment of a product—herein primarily on the performing of said operations on substrates.
Processing Chamber (or Chamber or Process Chamber): a region of a tool where a substrate resides or is contained within when it is receiving a process step or a portion of a process step that acts upon the substrate. Other parts of a tool may perform support, logistic or control functions to or on a processing chamber.
Process Flow: The order and nature of combination of multiple process steps that occur from one tool to at least a second tool. There may be consolidations that occur in the definition of the process steps that still constitute a process flow as for example in a single tool performing its operation on a substrate there may be numerous steps that occur on the substrate. In some cases these numerous steps may be called process steps in other cases the combination of all the steps in a single tool that occur in one single ordered flow may be considered a single process. In the second case, a flow that moves from a process in a first tool to a process in a second tool may be a two step process flow.
Production unit: An element of a process that is acted on by processing tools to produce products. In some cleanspace fabricators this may include carriers and/or substrates.
Robot: A machine or device that operates automatically or by remote control, whose function is typically to perform the operations that move a job between tools, or that handle substrates within a tool.
Round: Any closed shape of continuous curvature.
Substrates: A body or base layer, forming a product, that supports itself and the result of processes performed on it.
Tool: A manufacturing entity designed to perform a processing step or multiple different processing steps. A tool can have the capability of interfacing with automation for handling jobs of substrates. A tool can also have single or multiple integrated chambers or processing regions. A tool can interface to facilities support as necessary and can incorporate the necessary systems for controlling its processes.
Tool Body: That portion of a tool other than the portion forming its port.
Tool Chassis (or Chassis): A entity of equipment whose prime function is to mate, connect and/or interact with a toolPod. The interaction may include the supply of various utilities to the toolPod, the communication of various types of signals, the provision of power sources. In some embodiments a Tool Chassis may support, mate or interact with an intermediate piece of equipment such as a pumping system which may then mate, support, connect or interact with a toolPod. A prime function of a Tool Chassis may be to support easy removal and replacement of toolPods and/or intermediate equipment with toolPods.
toolPod (or tool Pod or Tool Pod or similar variants): A form of a tool wherein the tool exists within a container that may be easily handled. The toolPod may have both a Tool Body and also an attached Tool Port and the Tool Port may be attached outside the container or be contiguous to the tool container. The container may contain a small clean space region for the tool body and internal components of a tool Port. The toolPod may contain the necessary infrastructure to mate, connect and interact with a Tool Chassis. The toolPod may be easily transported for reversible removal from interaction with a primary clean space environment.
Tool Port: That portion of a tool forming a point of exit or entry for jobs to be processed by the tool. Thus the port provides an interface to any job-handling automation of the tool.
Tubular: Having a shape that can be described as any closed figure projected along its perpendicular and hollowed out to some extent.
Unidirectional: Describing a flow which has a tendency to proceed generally along a particular direction albeit not exclusively in a straight path. In clean airflow, the unidirectional characteristic is important to ensuring particulate matter is moved out of the cleanspace.
Unobstructed removability: refers to geometric properties, of fabs constructed in accordance with the present invention that provide for a relatively unobstructed path by which a tool can be removed or installed.
Utilities: A broad term covering the entities created or used to support fabrication environments or their tooling, but not the processing tooling or processing space itself. This includes electricity, gasses, airflows, chemicals (and other bulk materials) and environmental controls (e.g., temperature).
Vertical: A direction that is, or is close to being, parallel to the direction of gravitational force.
Vertically Deployed Cleanspace: a cleanspace whose major dimensions of span may fit into a plane or a bended plane whose normal has a component in a horizontal direction. A Vertically Deployed Cleanspace may have a cleanspace airflow with a major component in a horizontal direction. A Ballroom Cleanroom would typically not have the characteristics of a vertically deployed cleanspace.

While the invention has been described in conjunction with specific embodiments, it is evident that many alternatives, modifications and variations will be apparent to those skilled in the art in light of the foregoing description. Accordingly, this description is intended to embrace all such alternatives, modifications and variations as fall within its spirit and scope.

1) (canceled)

2) (canceled)

3) (canceled)

4) (canceled)

5) (canceled)

6) (canceled)

7) (canceled)

8) (canceled)

9) (canceled)

10) (canceled)

11) (canceled)

12) (canceled)

13) (canceled)

14) (canceled)

15) (canceled)

16) (canceled)

17) (canceled)

18) (canceled)

19) (canceled)

20) (canceled)

21) A method for processing a substrate, the method comprising the steps of:
forming a substrate fabricator comprising at least a first vertically deployed cleanspace, at least a first tool chassis and at least a first toolPod attached to the first tool chassis;
processing a least a first substrate in the first toolPod;
handling the first substrate at a toolport of the first toolPod within the first vertically deployed cleanspace;
removing the first toolPod from the factory from outside a primary cleanspace for repair; and
replacing a second toolPod onto the first tool chassis.

22) The method for processing a substrate of claim 21 wherein the second toolPod comprises a toolPod of a newer design.

23) The method of claim 21 additionally comprising the step of:
determining a use of licensed content via at least one of personnel and electronic systems of at least the first fabricator.

24) The method of claim 21 comprising the steps of:
designing a product while in communications with electronic systems of at least a first fabricator wherein the entity receives information from the said communications relating to licensable content that may be incorporated into the product;
contracting with at least a first fabricator to perform the method of claim 21; and
paying royalties for use of at least one of design blocks, process flows, assembly flows, or packaging intellectual property.

25) The method of claim 21 additionally comprising the steps of:
removing the first toolPod for repair;
shipping the first toolPod out of the first fabricator to a maintenance facility; and
disassembling the first toolPod at least in part to allow for a chamber lying within to have a maintenance process performed upon it.

26) The method of claim 25 additionally comprising the steps of:
reassembling the first toolPod after the maintenance process is performed; and
testing the first toolPod via placing the first toolPod upon either of a second tool chassis or a first toolPod test stand.

27) The method of claim 26 additionally comprising the step of:
shipping the tested first toolPod to a fabricator where the first toolPod is attached to either of the first tool chassis or a third tool chassis.

28) The method of claim 21 wherein:
the processing of the first substrate in the first toolPod comprises a step in an experimental process module.

29) The method of claim 21 wherein:
the chamber within the first toolPod was developed utilizing a first experimental toolPod which had been attached to a toolPod test stand.

30) The method of claim 21 wherein:
the substrate fabricator has at least a first toolPod wherein the first toolPod is located in a vertical orientation to at least a second toolPod wherein at least a portion of the first toolPod is above at least a portion of the second toolPod in a directly vertical direction.

31) The method of claim 21 additionally comprising the steps of:
dicing the substrate into chips; and
assembling the chips into packages.

32) The method of claim 31 additionally comprising the step of:
forming a conductive connection between a conductive contact on the respective package and another conductive surface not previously in conductive contact with the respective package.

33) The method of claim 21 additionally comprising the steps of:
communicating between a first fabricator which can perform the methods of claim 21 and at least a second fabricator which can perform the method of claim 21;
communicating between a customer and at least a collective combination of the first fabricator and the second fabricator with a request for a product with specified functionality; and
providing to a customer a product via at least one of the first or second fabricators, to the customer with function compliant with the request.

34) A method for preparing toolPods comprising the steps of:
obtaining a first toolPod without a processing chamber for processing wafers
obtaining a first process chamber for processing wafers in a controllable fashion; and
adding the first process chamber to the first toolPod to form a functional first toolPod for substrate processing.

35) The method of claim 34 additionally comprising the step of:
submitting a functional first toolPod for testing by a third party for characteristics of the first toolPod's function.

36) The method of claim 35 additionally comprising the steps of:
testing a functional first toolPod via the third party; and
receiving a declaration by the third party of the ability of the functional first toolPod to process wafers.

37) The method of claim 36 wherein at least the first toolPod is designed to have a minimal set of components such that the tool is targeted to perform a limited set of process conditions.

38) A method for qualifying products the method comprising the steps of:
contracting with at least a first fabricator to produce multiple substrates utilizing the method of claim 21 to produce a first substrate wherein the processing of the first substrate is performed in an order of steps occurring to a first process flow and utilizing the method of claim 21 to produce a second substrate wherein the processing flow of the second substrate is performed in an order of steps occurring to a second process flow, wherein the first process flow differs from the second process flow in at least one process step; and
testing the first and the second substrates to conform to a specification desired for the type of product embodied in the at least first and second substrates.

39) The method of claim 38 additionally comprising the steps of:
producing a product in a second fabricator wherein the first process flow represents the processing flow in the second fabricator; and
producing the product in a third fabricator wherein the second process flow represents the processing flow in the third fabricator.

40) The method of claim 39 additionally comprising the step of:
using the test results to decide between
producing a product in a second fabricator wherein the first process flow represents the processing flow in the second fabricator, and
producing the product in a third fabricator wherein the second process flow represents the processing flow in the third fabricator.
